(19) United States
(12) Patent Application Publication
(10) Pub. No.: US 2007/0178225 A1
(43) Pub. Date: Aug. 2, 2007

(54) Vapor deposition crucible, thin-film forming apparatus comprising the same, and method of producing display device

(76) Inventors: Keiji Takanosu, Yokohama (JP); Hiroyasu Matsuura, Yokohama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/637,805

(22) Filed: Dec. 13, 2006

(30) Foreign Application Priority Data
Dec. 14, 2005 (JP) JP 2005-359781

(51) Int. Cl. B05D 5/06; C23C 16/00

(52) U.S. Cl. 427/69; 118/726

(57) ABSTRACT

For lasting stable vapor deposition of a material for a long term, the present invention provides the vapor deposition crucible comprising an evaporation chamber defined by a container part of the material and an orifice plate controlling vapor pressure of the material evaporated therein, and a pressure-controlling chamber defined in a space between the orifice plate and a discharge plate through which the material is discharged to the exterior of the vapor deposition crucible. A protrusion extending outwardly from the pressure-controlling chamber and having a second opening on its distal end may be provided on the upper surface of the discharge plate, and a heater may be provided on the side surface of the protrusion to oppose the side surface of the protrusion with an insulation mechanism provided at a position higher than the heater but lower than the second opening. In the vapor deposition crucible, temperature of the pressure-controlling chamber may be kept higher than that of the evaporation chamber by the other heaters.

The present application claims priority from Japanese application JP 2005-359781 filed on Dec. 14, 2005, the content of which is hereby incorporated by reference into this application.

### BACKGROUND OF THE INVENTION

1. Field of the Invention

This invention relates to a production of an electronic device such as a display device comprising the step of vapor depositing an organic material, a vapor deposition crucible adapted for use in such production, and a thin film forming apparatus (organic thin film forming apparatus) using such a crucible.

2. Description of the Related Art

Various methods have been proposed for use in forming a thin film from an organic material. However, there are various process constraints unique to the organic material, and some materials had difficulty in the use for a stable vapor deposition. Recently, the so called organic EL panel which displays an image by a panel produced by the vapor deposition technology of such an organic material has been developed, outline of such development is as described below.

An organic EL panel (organic electroluminescent panel) displays an image by means of organic EL elements (organic electroluminescent elements) which are arranged in two dimensional pattern and which are driven by a current. An organic EL element generally has a laminate structure in which organic material layers such as a hole injection layer, a hole transfer layer, a luminescent layer (a light-emitting layer), an electron transfer layer, and an electron injection layer are sequentially deposited on a transparent substrate such as a glass plate, and an electric current is applied to this laminate structure in the direction of the lamination by a pair of electrodes formed on both sides thereof. At least one of the pair of electrodes is configured with a transparent electrode (allowing passage of the visible light). More specifically, a hole injection layer, a hole transfer layer, a light emitting layer, an electron transfer layer, and electron injection layer are deposited on the first electrode (which is typically an anode) formed on each pixel of the transparent substrate, the electron transfer layer (the uppermost layer of the laminate structure) is covered by a second electrode (which is typically the cathode) to flow an electric current between the first electrode and the second electrode. This results in the recombination of the carriers (the electron and the positive hole) injected in the laminate structure (luminescent layer), and the light is emitted. The intensity of the luminance is controlled by the current density of the current passing through the laminate structure, and the organic EL element can also be deemed as a capacitive display device, and it is sometimes indicated as a diode. Such organic EL elements (hereinafter simply referred to as “elements,” also) are arranged on the main surface of the substrate such as a substrate or a film in two dimensional pattern to constitute a display device, namely, an organic EL panel.

An image display device is constituted by combining this organic EL panel with functional components such as a driver circuit. These functional components may also be formed directly on the substrate of the organic EL panel. The organic EL panels include passive matrix type in which a plurality of first electrodes and a plurality of second electrode are arranged to cross each other so that a pixel is formed at each of the crossings, and active matrix-type in which an active element such as a thin film transistor and a first electrode driven by the active element are formed for each pixel. In the current organic EL panel, active matrix-type is the mainstream in view of realizing a high resolution and a high speed display. In the following, description is made by taking the active matrix-type organic EL panel for the example.

The organic material layers constituting the laminate structure formed on the transparent substrate are formed by heating an organic material in a vapor deposition crucible accommodated in a vacuum chamber to a temperature near its evaporation temperature for evaporation, and vapor depositing the evaporated organic material on the main surface of the transparent substrate introduced in the vacuum chamber. More specifically, a mask comprising a metal alloy called a metal mask having openings formed in a pattern corresponding to the arrangement of the pixels on the main surface of the transparent substrate is placed on the main surface of the transparent substrate introduced in the vacuum chamber. The evaporated organic material passes through the openings in the mask to be deposited at the predetermined regions (e.g., the regions corresponding to the pixels) on the main surface of the transparent substrate in the form of a thin film of the organic material. In the case of the deposition of the light emitting layer, the main organic material may be co-deposited with an additional material (e.g., another organic material) on the predetermined regions in the main surface of the substrate. A conventional vapor deposition crucible that has been used in forming the organic EL panel is described, for example, in Patent Document 1, and has the constitution as described below.

The vapor deposition crucible comprises an evaporation vessel accommodating the organic material, and this organic material to be evaporated accommodated in the evaporation vessel is evaporated to form a vapor deposited layer of the organic compound on the substrate placed in the vacuum chamber. An orifice is provided in this evaporation vessel in order to control the amount of the organic material evaporated in the evaporation vessel entering the vacuum chamber. The vapor deposition crucible is also provided with a hollow cylindrical crucible body having a bottom portion for accommodating the organic material to be evaporated, and a hollow cylindrical cap portion having a bottom portion with a diameter smaller than that of the crucible main body, and an orifice (opening) is formed at the bottom of this cap portion. A structure has also been proposed in which this cap portion is inserted in the crucible main body to form an evaporation chamber between the bottom portion of the crucible main body and the bottom portion of the cap portion.

Patent Document 2 discloses a vapor deposition process (mask vapor deposition) to form the layer of the organic material only at the predetermined regions of the substrate by covering the main surface thereof with a vapor deposition mask comprising a metal thin plate which has a plurality of holes corresponding to the pixels of the organic EL panel formed in its main surface. In this vapor deposition process, the substrate and the vapor deposition mask thermally expand by the influence of the radiant heat from the crucible at a high temperature, and displacement occurs between the positions on the substrate at which the organic material is to be deposited and the holes of the mask, and this results in the loss of the precision in the production of the organic EL panel. In order to prevent this problem, Patent Document 2 proposes provision of a protrusion on the upper side of the crucible in which the evaporated material is accommodated and evaporated, provision of a hole through this protrusion for passage of the evaporated material, and provision of a radiation blocking body near the protrusion at a position of the level equal to or lower than the opening (ejection end of the evaporated material) of the protrusion open to the exterior of the crucible. The radiation blocking body is formed at a distance from the upper surface (the surface on the side of the substrate) of the crucible, and is thermally insulated from the crucible.

Patent Document 1: Japanese Patent Laid-Open Publication No. 10-195639 (1998-195639)

Patent Document 2: Japanese Patent Laid-Open Publication No. 2004-214185

### SUMMARY OF THE INVENTION

FIG. 2(a) schematically shows an embodiment of the thin-film forming apparatus (organic thin-film forming apparatus) 100 which is used in producing the organic EL panel and the like. The thin-film forming apparatus 100 has a vacuum chamber 2 whose interior is kept at a pressure lower than the atmospheric pressure (hereinafter referred to as the “vacuum” for the convenience of description) by an exhaust apparatus (not shown), vapor deposition crucibles 1a and 1b in which the organic material is evaporated and from which the evaporated organic material is introduced to the interior of the vacuum chamber 2, and a purge system 13 for introducing an inert gas into the vacuum chamber 2. In the vacuum chamber 2, a stage 101 is provided for placing the substrate 103 which is the workpiece material, and this stage 101 is equipped with a heating apparatus 102 for heating the substrate 10. The two vapor deposition crucibles 1a and 1b have substantially the same structure except that the kinds of the organic materials accommodated therein may be different. The main surface of the substrate 103 on which the thin film of the organic material is formed, or the surface of the stage 101 on which the workpiece material in other words is placed opposite to the two vapor deposition crucibles 1a and 1b (namely, the orifice 32a to be described later which is provided on each vapor deposition crucible) with the intervening shutter 11. The metal mask is placed between the main surface of the substrate 103 and the shutter 11. Auxiliary shutters 50a and 50b having heaters 5 provided between the shutter 11 and the two vapor deposition crucibles 1a and 1b control the vapor deposition of the organic material onto the main surface of the substrate 103 together with the shutter 11. Amount of the organic material evaporated from the vapor deposition crucible 1a is monitored by a film thickness monitor 6a, and amount of the organic material evaporated from the vapor deposition crucible 1b is monitored by a film thickness monitor 6b, respectively. Excessive organic material scattered in the vacuum chamber 2 is adsorbed by shrouds 12 and 17 which are cooled. The vapor deposition crucibles 1a and 1b are mounted on installation ports 11a and 11b of the vacuum chamber 2, respectively, and the scattering directions of the organic material from the respective orifice are regulated by the separator plate 15.

FIG. 2(b) is a cross sectional view showing the constitution of the conventional vessel 33, namely, the crucible 1 which has been used as the vapor deposition crucibles 1a and 1b for the vapor deposition of the organic material as described above. The crucible 1 comprises a hollow tubular crucible body 31 having a bottom part 31A for accommodating an organic material 36 which is to be evaporated from the crucible 1, and a cylindrical cap portion 32 having a bottom portion 32A with the diameter smaller than that of the crucible main body 31, and an orifice 32a is provided on the bottom of the cap portion. The cylindrical crucible main body 31 and the cap portion 32 which are provided at one end with the bottom parts 31A and 32A, respectively, are formed on the other end with flanges 31B and 32B, respectively. The cap portion 32 is inserted in the upper side of the crucible main body 31 so that the flange 32B of the cap portion 32 is laid over the flange 31B of the crucible main body 31, and the flanges 31B and 32B are secured to each other. Thereby, an evaporation chamber 33A is formed between the organic material 36 stored in the bottom part 31A of the crucible main body 31 and the bottom part 32A of the cap portion 32. The crucible main body 31 having the cap portion 32 inserted therein is further inserted in a hollow cylindrical accommodation vessel 30 for heating by a heater 34 provided on the outer periphery of the accommodation vessel 30. Output of the heater 34 is adjusted according to the temperature measured by a thermocouple 35 embedded in the accommodation vessel 30.

As a preparation stage (starting stage) for the step of the vapor deposition of the organic material 36 on the substrate 103 by the crucible 1, heat from the heater 34 that has been turned on first elevates temperature of the crucible main body 31, and shortly afterward, temperature of the cap portion 32 starts to rise. When the heater 34 is turned off after the completion of the vapor deposition, the cap portion 32 is first cooled, and then, the crucible main body 31 with the heat remaining from the heater is cooled. As a consequence, immediately after turning off the heater 34, the organic material 36 keeps evaporating in the crucible main body 31 by the heat remaining in the heater 34. Under such condition, when the temperature of the cap portion 32 decreases to the level below the evaporation temperature of the organic material 36 by the progress of the cooling of the cap portion 32, the material evaporated from the crucible main body 31 deposits on the inner wall 32C and the outer wall (the surface opposing the crucible main body) of the cap portion 32 to become solidified. The evaporated organic material 36 also solidifies in the interior of the orifice 32a to block the orifice 21a. Such problem may not substantially arise if the process of the vapor deposition is kept until the organic material 36 accommodated in the crucible main body 31 is depleted and the heater is then turned off. However, even if the organic material 36 supplied to the bottom portion 31A of the crucible main body 31 seems to have completely depleted, the organic material 36 may remain, for example, in the minute gap between the flange 31B of the crucible main body 31 and the flange 32B of the cap portion 32, and this organic material 36 remaining in such gap is likely to invite sticking of the flange 31B to the flange 32B. This will result in the difficulty of separating the crucible main body 31 and the cap portion 32, or even if separated, tremendous extra effort for such separation, and maintenance work such as replenishing of the organic material 36 to the crucible main body 31 and washing of the crucible main body 31 will be extremely troublesome.

In the constitution of the conventional vessel 33 (crucible 1) for the vapor deposition of the organic material as described above, the organic material 36 scattering from the orifice 32a formed through the bottom portion 32A of the cap portion 32 is introduced into the vacuum chamber 2 of the thin-film forming apparatus 100 along the inner wall 32C of the cap portion 32, and upon completion of the vapor deposition step, the vapor of the organic material 36 that has been scattered in the cap portion 32 is cooled to become deposited on the inner wall 32C. In the subsequent vapor deposition step, the organic material 36 (e.g., a flake thereof) thus deposited on the inner wall 32C of the cap portion 32 falls from the inner wall 32C of the cap portion 32 to the bottom portion 32A to become deposited on the orifice 32a formed in the bottom portion 32A. When the diameter of the orifice 32a is reduced by such deposition, vapor deposition rate of the organic material 36 freshly evaporated in the crucible main body 31 on the substrate 103 becomes unstable.

In addition, the conventional vessel 33 (crucible 1) for the vapor deposition of the organic material as described above is constituted so that the flow of the vapor of the organic material 36 discharged from the orifice 32a formed in the bottom portion 32A of the cap portion 32 is formed along the inner wall 32C of the cap portion 32. However, since cross sectional area (diameter of the inner wall of the cap portion 32) perpendicular to the longitudinal axis of the cap portion 32 is large, vapor pressure of the organic material 36 in the cap portion 32 would not be increased. As a consequence, the vapor of the organic material 36 released from the orifice 32a will freely disperse in the cap portion 32.

FIG. 12 shows an embodiment of the patterning of the pixels in the display device (e.g., organic EL panel) in conventional vapor deposition mask. The vapor deposition mask 161 used in the so called mask vapor deposition comprises a metal sheet 162 provided with holes 164 corresponding to the pixels patterned on the main surface of the substrate 103 retained in a frame 163. The frame 163 gives tension to the metal sheet 162 to stretch the metal sheet 162 on the main surface of the substrate without sagging. By bringing this vapor deposition mask 161 in close contact with the main surface of the substrate 103, and spraying the evaporated particles 360 from the crucible 1 positioned below the vapor deposition mask 161, a layer of the material of the evaporated particles 360 can be formed on the main surface of the substrate 103 in the regions exposed within the holes 164 formed on the metal sheet 162. This procedure enables patterning of the crystals of the evaporated material on the main surface of the substrate 103 through the holes 164 formed in the vapor deposition mask 161. In this deposition step of the layer, radiant heat from the crucible 1 thermally expands the vapor deposition mask 161 and the substrate 103. Since the vapor deposition mask 161 is formed of a metal and the substrate 103 is formed of a glass, respectively in general, the thermal expansion rates thereof are different from each other. In addition, the substrate 103 is replaced with a fresh substrate 103 once the deposition step is over. Therefore, difference in thermal expansion is induced between the substrate 103 and the vapor deposition mask 161, and displacement of the pattern actually deposited from the predetermined position will occur on the substrate 103.

Conventional method used for preventing such displacement in the position of the vapor deposition is shown in FIG. 10. As shown in FIG. 10(A), vapor deposition source 200 comprises a plurality of crucibles 1 aligned in a direction transverse to the moving direction of the substrate 103 which is scanned against the vapor deposition source 200. In order to reduce transfer of the radiant heat from the crucibles 1 to the vapor deposition mask 161 and the substrate 103, a radiation blocking body 165 is provided above each crucible 1. FIG. 10(B) is a cross sectional view of one of the crucibles 1 provided in the vapor deposition source 200 cut along the moving direction (scanning direction) of the substrate 103. The radiation blocking body 165 is a plate member comprising a metal alloy such as stainless steel or aluminum alloy, and its main surface is specular finished to improve thermal reflection efficiency. If desired, the radiation blocking body 165 may comprise two or more plate members provided at a distance from each other. In order to prevent transfer of the radiant heat to the vapor deposition mask 161 and the substrate 103, the radiation blocking body 165 may also be cooled. In order to prevent the evaporated particles scattering from the opening formed on the upper surface of the crucible 1 from being deposited and crystallized on the radiation blocking body 165 so that scattering of the subsequent particles is hindered, and in order to prevent loss of the performance of the radiation blocking body 165, a protrusion 169 is formed on the upper surface of the crucible 1, and a discharge aperture 81 is formed on the upper end of the protrusion 169 so that the discharge aperture 81 is at a level beyond the level of the radiation blocking body 165 to the side of the substrate 103.

According to the Patent Document 2, application of the vapor deposition source 200 to the thin-film forming apparatus as shown in FIG. 10 prevents blockage of the scattering of the evaporated particles by the deposition of the evaporated material on the radiation blocking body 165 and loss of the film deposition performance of the evaporated material on the substrate 103, and the transfer of the radiant heat from the crucible 1 to the vapor deposition mask 161 and the substrate 103 is thereby reduced. However, temperature near the discharge aperture 81 actually decreases because the protrusion 169 having the discharge aperture 81 is in close vicinity of the radiation blocking body 165 which is being cooled, and a temperature gradient is formed from the interior of the crucible 1 to the distal end of the protrusion 169 due to the distance between the protrusion 169 and the heater 22 used for heating the crucible 1. As a consequence, while the material 36 which reached the evaporation temperature evaporates in the interior of the crucible 1, the evaporated material 360 experiences decrease in its temperature at the discharge aperture 81 on the upper surface of crucible 1, and accordingly, the evaporated material 360 crystallizes near the discharge aperture 81 to block the discharge aperture 81. The scattering of the evaporated material 360 from the crucible 1 is hindered thereby.

In order to solve the problems as described above, the present invention provides a novel vapor deposition crucible used for vapor deposition source of a thin-film forming apparatus. Representative structures thereof are as described below.

Structure 1: A vapor deposition crucible comprising: a container portion where material to be evaporated from the vapor deposition crucible is accommodated; an orifice plate having a first opening, the orifice plate being separated from the container portion by a first space; and discharge plate provided on outer side of the first space and separated from the orifice plate by a second space, and having a second opening which discharges the material to the exterior of the vapor deposition crucible; wherein

an evaporation chamber for the evaporation of the material is formed between the container portion and the orifice plate in the first space; and

the second space serves a pressure-controlling chamber in which the pressure is controlled in relation to the evaporation chamber.

Structure 2: A vapor deposition crucible comprising: a vessel having a portion where material to be evaporated from the vapor deposition crucible is accommodated; an orifice plate having a first opening and being provided in the vessel; and a discharge plate provided on outer side of the vessel to oppose the orifice plate, and having a second opening which discharges the material evaporated in the vapor deposition crucible to the exterior of the vapor deposition crucible; wherein

an evaporation chamber is formed in the vessel between the portion where the material is filled and the orifice plate; and

a space is defined between the orifice plate and the discharge plate, and this space serves a pressure-controlling chamber in which the pressure is controlled in relation to the evaporation chamber.

Structure 3: A vapor deposition crucible defined in the above structure 1 or 2 wherein

the second opening is formed at distal end of a protrusion extending from the discharge plate toward the exterior of the pressure-controlling chamber;

at least one reflection plate provided at a distance from the discharge plate and a cooling plate spaced from the reflection plate are arranged from the discharge plate in this order in the direction of the extension of the protrusion;

the reflection plate has a specular finished main surface on the side of the discharge plate; and

the cooling plate is connected to a cooling apparatus, and one of main surfaces of the cooling plate is wider than the main surface of the reflection plate, and distance between another of the main surfaces of the cooling plate and the discharge plate is equal to or shorter than distance between the distal end of the protrusion and the discharge plate.

When one of a pair of main surfaces of the discharge plate facing the orifice plate is defined as the first main surface, and another of the pair of main surfaces thereof on the other side of the first main surface is defined as the second main surface, the protrusion protrudes upward from the second main surface of the discharge plate which is also described as the upper surface of the vapor deposition crucible. In other words, when the pressure-controlling chamber is formed as a space extending between the orifice plate and the first main surface of the discharge plate, the protrusion extends to the exterior of the pressure-controlling chamber, and the second opening is formed at its tip (distal end). In Structure 3, the reflection plate, the cooling plate, and the cooling apparatus constitutes an “thermal insulator mechanism (insulation mechanism)” which thermally isolates the “vapor deposition crucible” from the “substrate” on which the material evaporated or sublimed in the interior of the vapor deposition crucible and scattered from the opening (second opening) is deposited to form a layer.

Structure 4: A vapor deposition crucible defined in the above structure 3, wherein

a heater is provided on sides of the protrusion, the pressure-controlling chamber, and the evaporation chamber,

the specular finished main surface of the reflection plate adjacent to the discharge plate opposes the heater with an intervening gap, and

the one of the main surfaces of the cooling plate is shielded from the heater by the reflection plate.

Structure 5: A vapor deposition crucible defined in the above structure 3, wherein

a plurality of (two or more) reflection plates are juxtaposed (aligned) at a distance between each other in the direction of the extension of the protrusion, between the discharge plate and the one of the main surfaces of the cooling plate.

Structure 6: A vapor deposition crucible defined in the above structure 2 or 3, wherein

the orifice plate is inserted in the interior of the vessel at its one end,

the one end of the vessel is provided with a support for supporting the orifice plate,

the discharge plate is formed with a side wall extending from the surface formed with the second opening to the exterior of the end of the vessel, and

the pressure controlling chamber is formed between exterior periphery of the end of the vessel, and the surface of the discharge plate and the side wall thereof covering the exterior (outer) periphery.

Structure 7: A vapor deposition crucible defined in the above structure 6 further comprising a heater provided on sides of the protrusion, the pressure-controlling chamber, and the evaporation chamber, wherein

the heater is provided for the discharge plate at each of the surface thereof, the side wall thereof extending from the surface along an outer periphery of the pressure-controlling chamber, and the protrusion thereof having the second opening and extending from the surface thereof so that the heater is directly in contact with the each of the surface, the side wall, and the protrusion.

Structure 8: A vapor deposition crucible defined in the above structure 6 further comprising a heater provided on sides of the protrusion, the pressure-controlling chamber, and the evaporation chamber and a heater case accommodating the heater, wherein

the heater case is provided with each of functions of the surface, the side wall, and the protrusion of the discharge plate.

Structure 9: A vapor deposition crucible defined in the above structure 2 or 3, wherein

the first opening is formed as a gap defined between the orifice plate and the side surface of the vessel opposite thereto.

Structure 10: A vapor deposition crucible defined in any one of the above structures 1 to 3, wherein

vapor pressure of the material in the pressure-controlling chamber is kept to the level not exceeding that in the evaporation chamber where the material is evaporated.

Structure 11: A vapor deposition crucible defined in any one of the above structures 1 to 3, wherein the structure further comprises

a first heater for heating the evaporation chamber and a second heater for heating the pressure-controlling chamber, the first heater and the second heater being controlled independently from each other.

Structure 12: A vapor deposition crucible defined in any one of the above structures 1 to 3, wherein the evaporation chamber is maintained at a temperature lower than that of the pressure-controlling chamber.

Structure 13: A thin-film forming apparatus having the vapor deposition crucible of any one of the above structure 1, 2, or 3 as a vapor deposition source, comprising

a chamber into which a substrate on which the material evaporated in the evaporation chamber is to be deposited is introduced, and

at least one vapor deposition crucible which is connected to the chamber by the second opening, wherein

the chamber is maintained at a pressure lower than any of the evaporation chamber and the pressure-controlling chamber.

Structure 14: A thin-film forming apparatus having the vapor deposition crucible of the above structure 3 as a vapor deposition source, comprising

a chamber into which a substrate on which the material evaporated in the evaporation chamber is to be deposited is introduced,

a vapor deposition mask which has a plane formed with a plurality of holes corresponding to the pixel pattern to be formed on a main surface of the substrate, and which is brought in close contact with the main surface of the substrate at the plane, and

at least one vapor deposition crucible which is connected to the chamber by the second opening, wherein

in the chamber, the vapor deposition mask is provided such that the main surface of the substrate having the plane of the vapor deposition mask closely contacted therewith opposes the second opening of the vapor deposition crucible, and

the chamber is maintained at a pressure lower than any of the evaporation chamber and the pressure-controlling chamber.

In the present invention, according to consideration on the phenomenon of vapor deposition of the organic material thin film by the vapor deposition crucible as described above, the present invention also provides “a method for producing a display device” as a novel vapor deposition technique. A representative “production method” is as described below.

Production method 1: A method for producing a display device by vapor depositing an organic material on main surface of a substrate, comprising the steps of:

evaporating the organic material in a first space;

introducing the evaporated organic material from the first space to a second space in which vapor pressure of the organic material is maintained to the level not higher than the first space; and

introducing the evaporated organic material which has been introduced in the second space to a third space which is maintained at a pressure lower than the first space and the second space, and depositing the evaporated organic material onto the main surface of the substrate disposed in the third space.

Production method 2: In the production method 1,

the second space is maintained at a temperature higher than that of the first space.

Production method 3: In the production method 2,

the second space and the third space are connected by an opening formed in a member separating the second space and the third space, and

the evaporated organic material is introduced from the second space to the third space through the opening while the opening is maintained at a temperature not lower than the temperature of the second space.

Production method 4: In the production method 3,

space of the third space surrounding the opening is cooled to a temperature lower than the temperature of the opening.

Production method 5: In the production method 2 or 3,

the step of the vapor deposition of the evaporated organic material onto the main surface of the substrate is terminated by stopping the heating of the second space after stopping the heating of the first space.

In the present invention, the vapor of the material (the organic material) which evaporates from the opening portion of the orifice plate defining the crucible main body (evaporation chamber) to the exterior of the crucible main body is less likely to be cooled after the completion of the vapor deposition since the orifice plate is covered by the cap portion which directly receive the heat from the heater. This prevents solidification of the material that has evaporated from the crucible main body on the surface of the cap portion opposing the crucible main body, or solidification of the material in the interior of the opening portion which functions as the orifice. Accordingly, separation of the crucible main body and the cap portion is readily realized, and introduction of the material into the crucible main body is facilitated.

In addition, deposition of the evaporated material near the orifice plate (on the upper side of the upper surface of the orifice in the crucible) is prevented, and attachment of the peeled deposited material to the opening of the orifice is also prevented, and therefore, the rate of the vapor deposition is stabilized.

When the gap between the side surface of the orifice plate and the inner wall of the crucible main body is used for the orifice hole, the temperature of the orifice hole increases to an even higher temperature when the heater is energized and deposition of the material near the orifice hole will be prevented.

By constituting the cap portion to have a structure capable of directly receiving the heat from the heater, the opening portion (discharge aperture) of the cap portion can be designed to have a smaller diameter and a larger hole length since the clogging of the vaporized material in the hole and the resulting increase in the flow-passage resistance of the material in the hole will be avoided due to the increased temperature of the opening portion. In addition, leakage of the vaporized material from the gap between the crucible main body and the cap portion will also be avoided. Therefore, such problem will not arise even if the opening portion of the cap portion has a smaller diameter and a larger hole length, and distribution of the vapor deposition of the material on the main surface of the substrate can be controlled in a larger degree of freedom when the vaporized material is discharged from the vapor deposition crucible and finally deposited on the substrate.

The crucible as described above used in the mask vapor deposition using a vapor deposition mask is provided with the thermal insulator mechanism (insulation mechanism) as described above. This reduces heat transfer of the radiant heat from the crucible to the vapor deposition mask and the substrate, and insulating efficiency between the crucible and the vapor deposition mask and the substrate is maintained even after prolonged use of the crucible. Therefore, displacement in the position of the vapor deposition on the major surface of the substrate during the mask vapor deposition can be reduced to enable the production of a high precision display device. In addition, decrease in the temperature of the discharge aperture of the crucible and the resulting clogging of the discharge aperture associated with the cooling of the vapor deposition mask and the substrate will be prevented, and amount of the evaporated material discharged from the crucible will be stabilized for a prolonged time (period).

### BRIEF DESCRIPTION OF THE DRAWINGS

FIG. 1 is a cross sectional view showing the constitution of the crucible of Example 1 according to the present invention;

FIG. 2 is a cross sectional view showing the constitution of a conventional vessel, namely, a crucible used for vapor deposition of organic materials;

FIG. 3 is a cross sectional view showing the deposition of the evaporated material near the discharge aperture of the crucible of Example 1 according to the present invention;

FIG. 4 is a conceptual view showing the amount of the material deposited on the discharge aperture 81 after the completion of the vapor deposition in relation to the temperature difference between the opening portion 71 of the orifice plate 7 and the discharge aperture 81 for the crucible of Example 1 according to the present invention;

FIG. 5 is a conceptual view showing the relation of the quotient obtained by dividing the flow-passage resistance value of the opening portion 71 of the orifice plate 7 by the flow-passage resistance value of the discharge aperture 81 of the upper pressure-controlling chamber and the temperature of the discharge aperture 81, and its relation to the presence and absence of the condensation for the crucible of Example 1 according to the present invention;

FIG. 6 is a perspective view showing the cylindrical crucible of Example 1 according to the present invention;

FIG. 7 is a perspective view showing the rectangular parallelepiped crucible of Example 1 according to the present invention;

FIG. 8 is an equivalent circuit diagram which schematically shows the display device produced by using the vapor deposition crucible and the vapor deposition method of the organic material according to the present invention;

FIG. 9 is a cross sectional view of a pixel of the display device shown in FIG. 8;

FIG. 10A is a schematic perspective view of the conventional thin film forming apparatus for mask vapor deposition, and FIG. 10B is a schematic cross sectional view of a vessel (crucible) for organic vapor deposition equipped in such apparatus;

FIG. 11 is a cross sectional view showing the constitution of crucible for mask vapor deposition of Example 2 according to the present invention;

FIG. 12 is a schematic view showing the mask vapor deposition;

FIG. 13 is a view showing application of the vapor deposition crucible 1 of Example 2 according to the present invention for mask vapor deposition;

FIG. 14 is a view showing another application of the vapor deposition crucible 1 of Example 2 according to the present invention for mask vapor deposition;

FIG. 15 is a view showing the vapor deposition crucible of Example 3 according to the present invention in which the opening portion 71 is formed as a gap between the orifice plate 7 and the crucible main body 4; and

FIG. 16 is a cross sectional view showing another structure of the vapor deposition crucible of Example 2 according to the present invention for mask vapor deposition.

### DETAILED DESCRIPTION OF THE PREFERRED EMBODIMENT

The embodiments of the present invention are described below in detail by referring the drawings of the examples.

### EXAMPLE 1

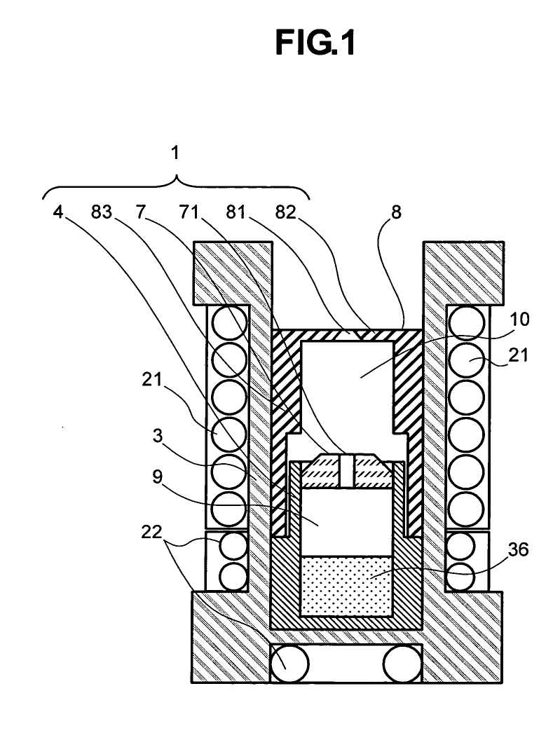

FIG. 1 is a cross sectional view showing the constitution of the crucible according to the present invention. The vapor deposition crucible 1 is inserted in a cylindrical heater case 3 provided with an upper heater 21 and a lower heater 22 for heating. The upper and the lower heaters 21 and 22 are sheath-type heaters which can be controlled independently from each other.

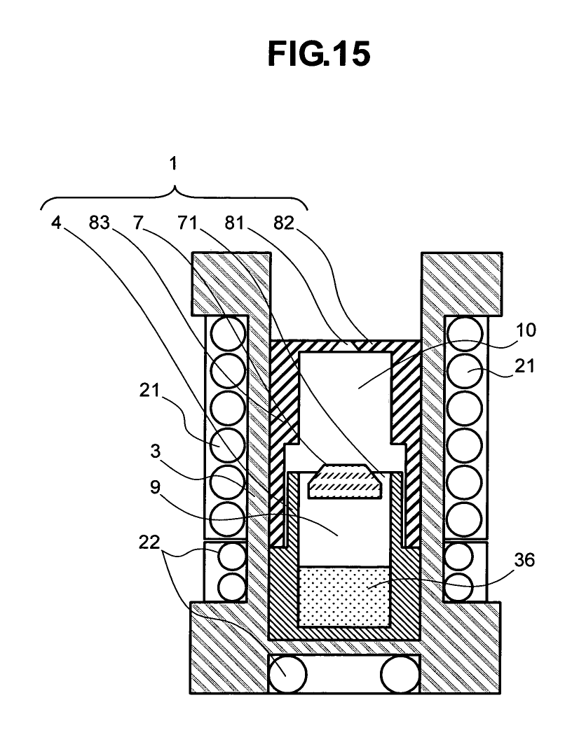

One end of the longitudinal axis of the cylindrical heater case 3 is formed with a bottom surface, and the other end of the heater case 3 is open in contrast to the bottom end. In the following description, the constitution of the vapor deposition crucible 1 is described by referring the end of the heater case 3 as the “lower” and the other end as the “upper”. The vapor deposition crucible 1 has a crucible main body 4 which is provided in the heater case 3 on the lower side, and the bottom of the crucible main body 4 is supported by the bottom of the heater case 3. A space 1e defined in the interior of the crucible main body 4 to include the bottom surface of the crucible main body 4 is used as a part of the vapor deposition crucible 1 for filling the material (organic material 36) which is evaporated from the crucible. Inner wall of the crucible main body 4 extends upwards from the bottom, for example, in the form of a cylinder. An orifice plate 7 is provided in the crucible main body 4 to be opposite to the space (defined as a part of the interior space of the crucible main body 4) in which the organic material 36 is filled (or the organic material 36 filled in such space) across an intervening space 9. This space 9 which is defined by the organic material 36 filled and remaining in the crucible main body 4 and the orifice plate 7 is hereinafter referred to as an evaporation chamber or a material evaporation chamber. The orifice plate 7 is formed with an opening portion 71 which control vapor pressure of the organic material 36 evaporated in the evaporation chamber 9. The opening portion 71 is not necessarily formed in the orifice plate 7, and it may be formed as a gap of particular width between the crucible main body 4 and the orifice plate 7 as will be described in relation to FIG. 15. The space surrounded by the bottom, the inner wall, and the orifice plate 7 of the crucible main body 4 is in communication with its exterior only through the opening portion 71 (namely, the orifice) unless some unexpected “leak” occurs between the inner wall and the orifice plate 7 of the crucible main body 4.

Accordingly, the orifice plate 7 is also referred to as the open end orifice plate. An inner volume of the evaporation chamber 9 can vary depending on the amount of the organic material 36 stored or remaining in the crucible main body 4. Since the function of the vapor deposition crucible according to the present invention is determined by relative relation between the vapor pressure of the organic material 36 in the evaporation chamber 9 and the vapor pressure of the organic material 36 in the pressure-controlling chamber 10, the variation in the volume of the evaporation chamber 9 is negligible. The orifice plate 7 may be supported at the desired position in the crucible main body 4 by a support (not shown in FIG. 1) provided by forming a shoulder or protrusion on the inner wall of the crucible main body 4, or by narrowing the cross section of the crucible main body 4 perpendicular to the longitudinal axis thereof.

In the heater case 3, a cap 8 having a surface formed with a discharge aperture 81 is provided above the crucible main body 4. This discharge aperture 81 is an opening from which the vapor of the organic material 36 formed in the vapor deposition crucible 1 is released, and the surface of the cap 8 formed with this aperture is hereinafter also referred to as a discharge plate 82. In the heater case 3, the discharge plate 82 is provided above the orifice plate 7 with an intervening space. The discharge aperture 81 is preferably placed to oppose the opening portion 71 of the orifice plate 7. The cap 8 shown in FIG. 1 has a side wall 83 extending from the periphery of the discharge plate 82 toward the outer periphery of the crucible main body 4, and an open end of the crucible main body 4 into which the orifice plate 7 is inserted and a part of the outer wall of the crucible main body 4 extending from the open end toward the bottom (the part of the outer wall on the side of the open end, an upper side thereof) are covered with the cap 8 having the discharge plate 82 and the side wall 83. In other words, the cap 8 covers the upper part of the crucible main body 4 having the orifice plate 7 fitted therein.

The space 10 spacing the discharge plate 82 and the orifice plate 7 has the function of adjusting the vapor pressure of the organic material 36 in this space 10 (namely, vapor pressure of the organic material 36 released from the opening portion 71 of the orifice plate 7) in relation to the vapor pressure of the organic material 36 in the evaporation chamber 9, and therefore, this space 10 is hereinafter also referred to as a pressure-controlling chamber. In the vapor deposition crucible 1 shown in FIG. 1, the pressure-controlling chamber 10 is surrounded by inner surface of the side wall 83 of the cap 8 and the outer periphery of the crucible main body 4 covered by the cap 8. The vapor pressure of the organic material 36 is a factor which characterizes the function of the vapor deposition crucible 1 and the production method of the display device according to the present invention, and in the pressure-controlling chamber 10, this vapor pressure is discussed as a value different from the so called saturated vapor pressure (which increases with the increase in the temperature). On the other hand, the vapor pressure of the organic material 36 in the evaporation chamber 9 is discussed with regard to the space enclosed by the crucible main body 4 and the orifice plate 7 from which the space occupied by the organic material 36 (which exists in solid or liquid state) has been subtracted.

The crucible main body 4, the orifice plate 7, and the cap 8 as described above are formed of a refractory metal such as graphite, molybdenum, or tungsten generally used in the art for the crucible material, or an alloy thereof.

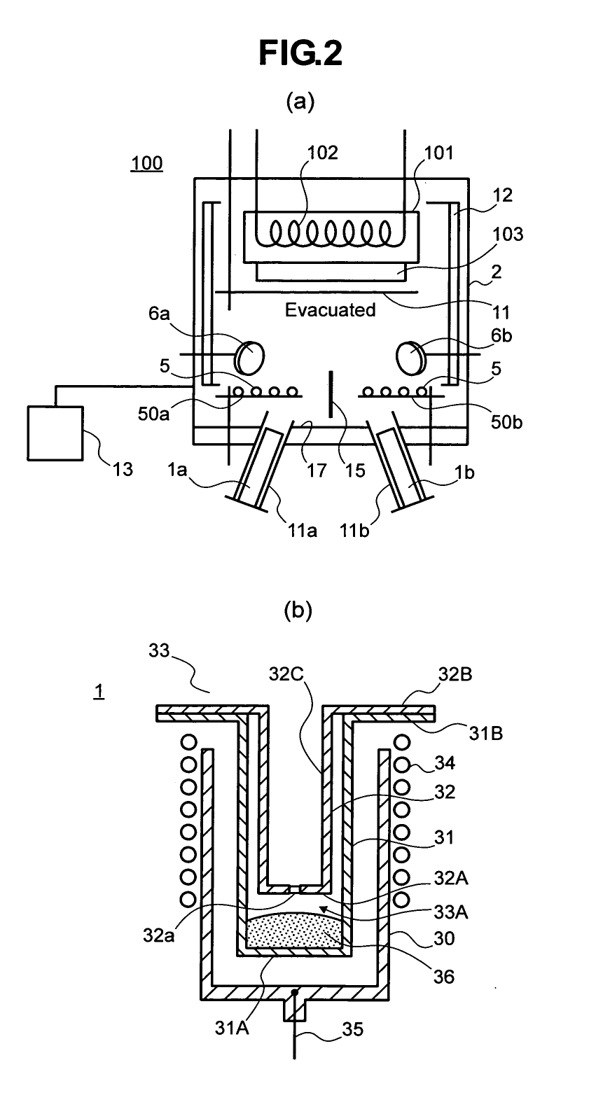

In the vapor deposition crucible 1 configured as described above, a part in which the material is filled (the space occupied by the organic material 36 before the evaporation or sublimation), the evaporation chamber 9 defined by the orifice plate 7 which controls the vapor pressure of the organic material 36, and the pressure-controlling chamber 10 formed in the space between the orifice plate 7 and the discharge plate 82 (cap 8) are arranged. The upper surface of the cap 8 (the discharge plate 82) is likely to experience temperature decrease by the radiation since this part is exposed to the exterior of the vapor deposition crucible 1. However, by bringing the side wall 83 of the cap 8 in contact with the inner wall of the heater case 3, decrease in the temperature of the cap 8 (the discharge aperture 81) is suppressed by the heat supplied from the heater case 3. In this example, the heater case 3 has the upper heater 21 and the lower heater 22 whose temperature can be controlled independently from each other. The upper heater 21 is provided along the inner wall of the heater case 3 which opposes the side wall 83 of the cap 8 to predominantly determine the temperature of the pressure-controlling chamber 10. The lower heater 22 is provided along the inner wall of the heater case 3 which is in contact with the crucible main body 4 to determine the temperature of the evaporation chamber 9. In this example, the temperature of the upper heater 21 for the pressure-controlling chamber, so to speak is set at a temperature higher than the lower heater 22 of the evaporation chamber 9, so to speak. The vapor deposition crucible 1 being constituted and functioning as described above was connected to a vacuum chamber 2 of the thin-film forming apparatus as shown in FIG. 2(a) to vaporize the organic material 36 in the vapor deposition crucible 1, and thereby the material was deposited on the main surface of the substrate 103 placed in the vacuum chamber 2.

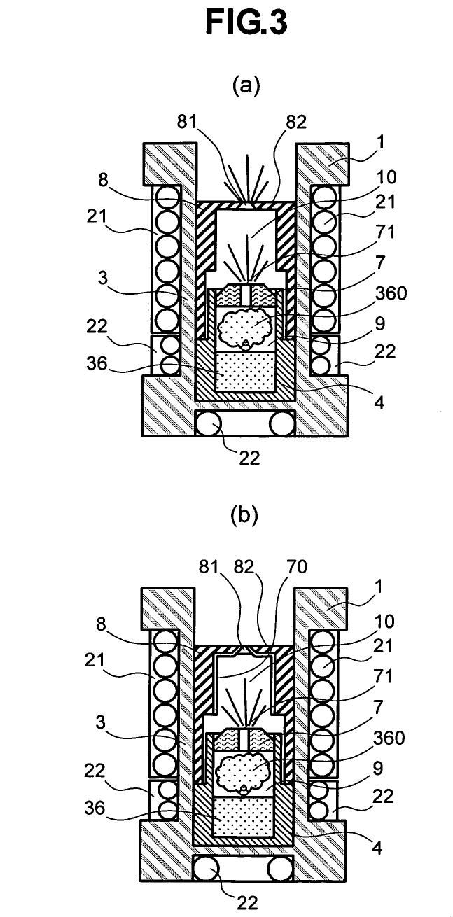

As shown in FIG. 3(a), the organic material 36 is evaporated (by sublimation) and vaporized in the evaporation chamber 9. The vaporized organic material 360 passes through the opening portion 71 of the orifice plate 7 and enters into the pressure-controlling chamber 10, and then to the vacuum chamber (the chamber at a reduced pressure) without depositing on the discharge aperture hole 81 maintained at the evaporation temperature to be deposited on the main surface of the substrate placed in the vacuum chamber. On the other hand, when the upper heater 21 is set at a temperature lower than the temperature of the lower heater 22 as shown in FIG. 3(b), vapor deposition on the main surface of the substrate does not proceed even though the evaporation of the organic material 36 continues in the evaporation chamber 9 kept at a high temperature because the temperature of the discharge aperture hole 81 is low and the vaporized organic material 360 partly condenses at the pressure-controlling chamber 10 to become deposited on the discharge aperture hole 81. The vaporized organic material 360 also deposits on the inner wall of the cap 8 to form a layer 70 of the organic material to block the discharge aperture hole 81, and impurities are also formed in the course of decomposition associated with the condensation.

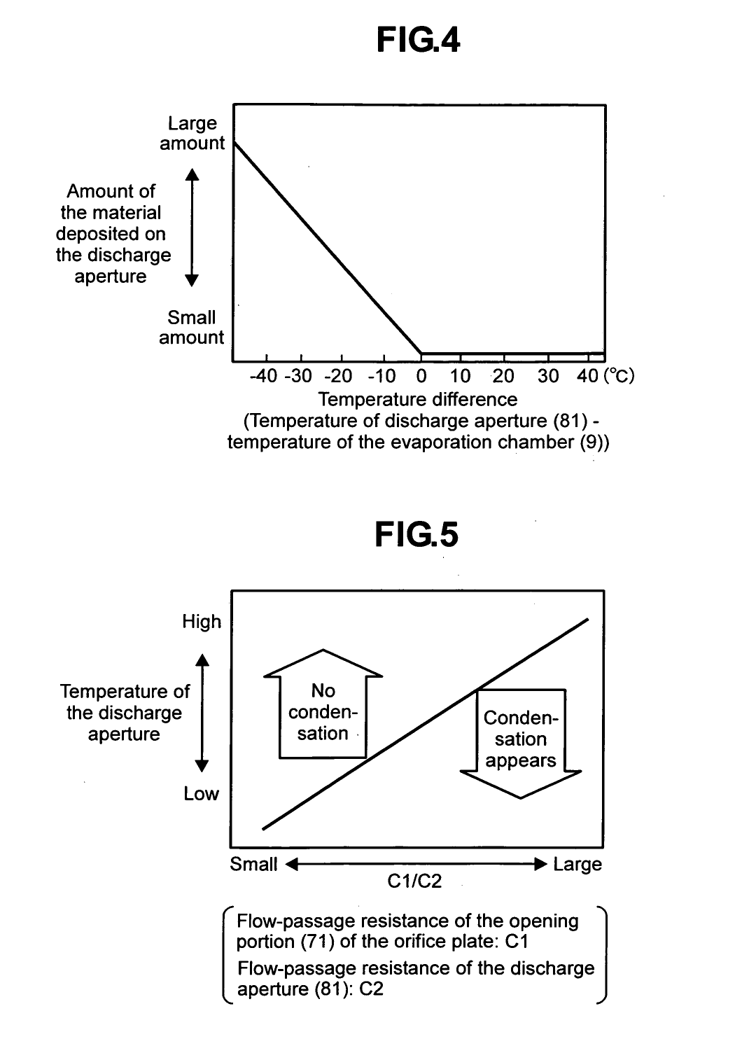

Next, the inventors of the present invention will consider about the difference in the thin film formation ability between the vapor deposition crucible 1 according to the example as described above, and the vapor deposition crucible 1 in the comparative example by referring to FIGS. 4 and 5.

FIG. 4 shows amount of the material 70 deposited on the discharge aperture hole 81 after the completion of the vapor deposition in relation to the temperature difference between the opening portion 71 of the orifice plate 7 and the discharge aperture hole 81 as described above. When the temperature of the material evaporation chamber 9 is lower than the temperature of the discharge aperture 81, deposition of the material on the discharge aperture 81 does not occur. On the contrary, when the temperature of the material evaporation chamber 9 is higher than the temperature of the discharge aperture 81, deposition of the material on the discharge aperture 81 occurs, and the deposition amount of the material increases with the increase in the temperature difference.

The deposition of the material 70 on the inner wall of the pressure-controlling chamber 10 including the orifice plate 7 proceeds gradually in the course of the vapor deposition, and on reaching the state that the opening portion 71 of the orifice plate 7 is covered with the material 70 deposited, discharge of the evaporated material from the opening portion 71 is inhibited. This results in the change of the amount of the evaporated material that reaches to the pressure-controlling chamber 10, and the amount of the evaporated material finally exiting from the discharge aperture 81 of the vapor deposition crucible 1, namely, the vapor deposition rate becomes unstable.

According to an analysis by the inventors of the present invention, the pressure of the evaporation chamber 9 and the pressure-controlling chamber 10 are associated with the relation shown in FIG. 4. More specifically, higher temperature of the evaporation chamber 9 results in the higher the pressure of the evaporation chamber 9 due to the increase in the amount of the material evaporated in the evaporation chamber 9, and on the contrary, lower temperature of the evaporation chamber 9 results in the lower pressure of the evaporation chamber 9. In the meanwhile, the evaporated material (the vaporized organic material 360) passes through the opening portion 71 of the orifice plate 7, and the pressure of the evaporation chamber 9 is limited by this opening portion 71. As the evaporated material enters from the evaporation chamber 9 to the pressure-controlling chamber 10, vapor pressure of the evaporated material in the pressure-controlling chamber 10 increases, and this in turn invites increase in the amount of the evaporated molecule per unit area in the pressure-controlling chamber 10. In such situation, when the temperature of the pressure-controlling chamber 10 is lower than the temperature of the evaporation chamber 9, the evaporated organic material 360 is likely to become condensed in the pressure-controlling chamber 10, and in particular, near the discharge aperture 81 whose temperature is likely to become lower, the evaporated organic material 360 or its decomposition product forms the material layer 70. This phenomenon is assumed to be caused by the fact that, when an excessive amount of the evaporated organic material 360 flows from the evaporation chamber 9 into the pressure-controlling chamber 10, vapor pressure of the organic material 360 in the pressure-controlling chamber 10 approaches its saturation vapor pressure, and that, when the temperature of the pressure-controlling chamber 10 is low, the saturation pressure is also low.

Such analysis confirmed the superiority of vapor deposition crucible 1 constituted and operated so that the temperature of the discharge aperture 81 of the pressure-controlling chamber would not be lower than the temperature of the evaporation chamber 9 as well as the method for producing a thin film of an organic material according to the present invention. The inventors of the present invention understood that the relation between the temperature and the pressure as described above was the results of the ratio between the volume ratio of the evaporation chamber 9 to the pressure-controlling chamber 10, and the ratio of flow-passage resistance of the opening portion 71 of the orifice plate 7 and the discharge aperture 81.

Next, the inventors of the present invention investigated the relation between “the ratio of flow-passage resistance between the opening portion 71 of the orifice plate 7 and the discharge aperture 81 in the vapor deposition crucible 1” and “condensation of the vaporized organic material 360 in the pressure-controlling chamber 10.” FIG. 5 shows presence and absence of the condensation of the organic material 360 for the combination of the quotient obtained by dividing the flow-passage resistance value of the opening portion 71 of the orifice plate 7 by the flow-passage resistance value of the discharge aperture 81 of the pressure-controlling chamber 10 and the temperature of the discharge aperture 81 under the condition that the volume of the evaporation chamber 9 is the same as the volume of the pressure-controlling chamber 10. As demonstrated in FIG. 5, the phenomenon of condensation can be suppressed when the pressure of the pressure-controlling chamber 10 is sufficiently reduced by controlling the flow-passage resistance of the opening portion 71 of the orifice plate 7 to the level not higher than the flow-passage resistance of the discharge aperture 81 of the pressure-controlling chamber 10, even if the temperature of the discharge aperture 81 of the pressure-controlling chamber were low.

This reveals that the vapor deposition crucible 1 according to the present invention can be realized by using the conventional vapor deposition crucible in which the temperature of the upper heater 21 can not be set independently from the temperature of the lower heater 22 by arranging the crucible main body 4 having the orifice plate 7 mounted in its inside and the cap 8 having the discharge aperture 81 opposing the orifice plate 7 (opening portion 71) in the manner as described in this example, and forming the discharge aperture 81 of the cap 8 to a size larger than the opening portion 71 of the orifice plate 7. The thus constituted vapor deposition crucible 1 may be connected to the vacuum chamber 2 of the thin-film forming apparatus of FIG. 2(a) so that the discharge plate 82 of the cap 8 would be exposed to the space at a reduced pressure in the vacuum chamber 2. Accordingly, the organic material 36 evaporated from the evaporation chamber 9 (first space) in the vapor deposition crucible 1 is introduced into the pressure-controlling chamber 10 (second space) in which the vapor pressure is kept to the level not higher than the evaporation chamber 9, and then, to the vacuum chamber 2 (third space) maintained at a pressure lower than the evaporation chamber 9 and the pressure-controlling chamber 10 for vapor deposition onto the substrate 103 placed in the vacuum chamber 2.

In this step, the size of the discharge aperture 81 is preferably limited to a certain degree to thereby control the vapor pressure of the organic material 36 in the pressure-controlling chamber 10 to the level not higher than the vapor pressure of the evaporation chamber 9. This will avoid the situation that the pressure of the pressure-controlling chamber 10 is by far lower than the pressure of the evaporation chamber 9 which may result, for example, in the adiabatic expansion of the vaporized organic material 360 discharged from the opening portion 71 that invites decrease in the temperature of the interior of the pressure-controlling chamber 10 inviting deposition of the vaporized organic material 360 on the inner wall of the pressure-controlling chamber 10. For example, the aperture area of the discharge aperture 81 may be designed to the range of up to 5, and more preferably, up to 2 folds of the opening portion 71 of the orifice plate 7. The size of the discharge aperture 81 in relation to the opening portion 71 of the orifice plate 7, however, does not basically have to be considered in other examples of the vapor deposition crucible 1 of the present invention where the pressure-controlling chamber 10 is controlled to a temperature higher than that of the evaporation chamber 9. However, in view of controlling the temperature of the pressure-controlling chamber 10 to a temperature which avoids the decomposition of the organic material 36, the size of the discharge aperture 81 is preferably designed to be larger than that of the opening portion 71 of the orifice plate 7 depending on the temperature of the pressure-controlling chamber 10.

In the vapor deposition crucible 1 according to this example, the evaporation chamber 9 and the pressure-controlling chamber 10 can be independently controlled to a temperature designed to correspond to various levels of flow-passage resistance as described above by the upper heater 21 and the lower heater 22. In addition, the crucible structure and the vapor deposition method as described above may be applied to the vapor deposition using either the organic material of the type which undergo sublimation from solid to gas or the organic material of melting type which experiences change from solid to liquid and then, liquid to gas. The crucible structure and the temperature control according to the present invention also enables suppression of the deposition of the material to the opening portion 71 of the orifice plate 7 or to the discharge aperture 81 after the completion of the vapor deposition step, and therefore, the steps such as refilling of the material to the vapor deposition crucible 1 (crucible main body 4) can be accomplished in a short time.

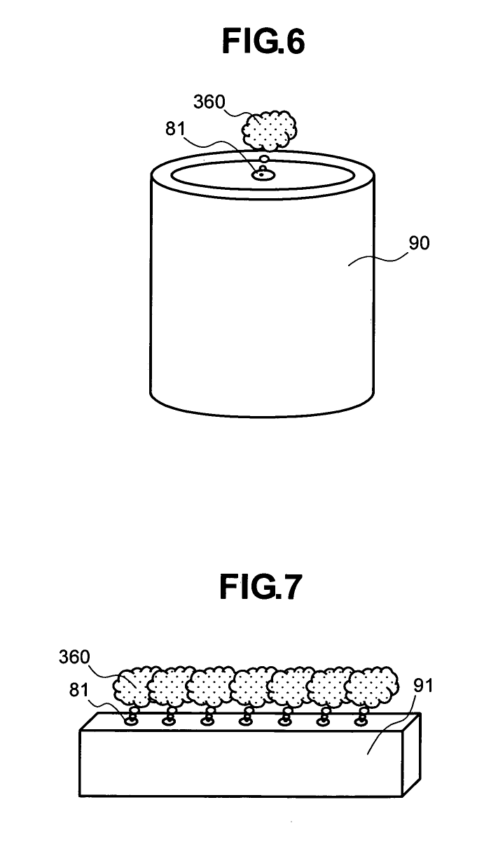

The vapor deposition crucible 1 as described above according to this example may be have a wide variety of shape such as cylindrical vapor deposition crucible 90 as shown in FIG. 6 or rectangular parallelepiped vapor deposition crucible 91 as shown in FIG. 7 as long as it has a cross sectional structure as shown in FIG. 1 or similar cross sectional structure. The vapor deposition crucible 91 is a linear vapor deposition source (line source) produced by arranging a plurality of structures each comprising a combination of the evaporation chamber 9 and the pressure-controlling chamber 10 in linear configuration. The vapor deposition crucible 1 of this example is capable of conducting an efficient vapor deposition of the organic material with no decomposition or deterioration on the main surface of the substrate as typically represented by the substrate of an organic electroluminescent display device. In particular, production efficiency of the electronic device can be improved by arranging the discharge aperture 81 in opposed relationship to the substrate of the electronic device, and scanning in the direction perpendicular to the arrangement of the above-mentioned structure.

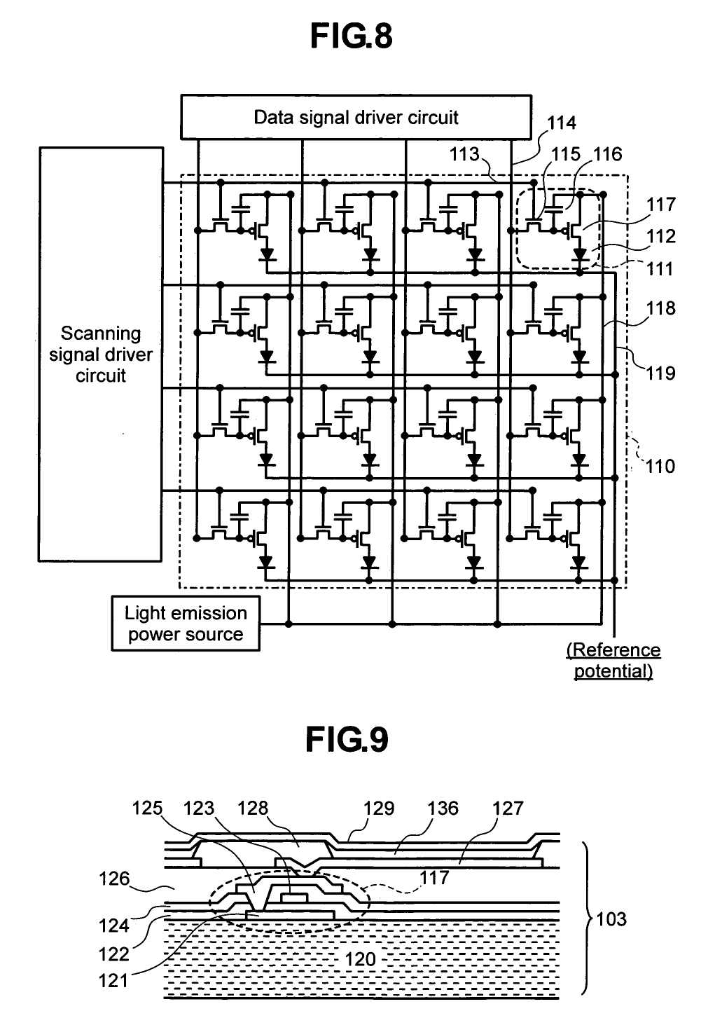

As a typical example of the display device produced by using the vapor deposition crucible or the method for producing a thin film according to the present invention, an active matrix-type organic electroluminescent display device is described. FIG. 8 is an equivalent circuit diagram which schematically shows the organic electroluminescent display device, and FIG. 9 is a cross sectional view of one pixel of the plurality of pixels constituting the organic electroluminescent display device. When such organic electroluminescent display device is produced by the thin-film forming apparatus shown in FIG. 2(a), at least a display region (pixel array, the region surrounded by the chain line) 110 is formed on the main surface of the substrate 103. The display region 110 (the main surface of the substrate 103) is formed with a plurality of pixel regions 111 (the regions surround by the broken line) in two dimensional manner. In the display region 110, a plurality of scanning lines 113 which control an operation (light emitting operation) of the organic EL element 112 provided in each pixel region 111 are aligned in first direction (vertical direction in FIG. 8), and a plurality of data lines 114 which supply the image data to be displayed on the display region 110 to each pixel region 111 are aligned in second direction (horizontal direction in FIG. 8) perpendicular to the first direction.

Each data line 114 extends in the first direction, and sequentially supplies the image data to a group of corresponding pixel regions 111 (arranged in the first direction). Each scanning line 113 extends in the second direction, and turns on the switching element 115 provided in a group of corresponding pixel regions 111 (arranged in second direction). Each pixel region 111 takes the image data from one of the corresponding data lines 114 to store the data in its capacitor 116 while the switching element 115 is turned on by one of the scanning lines 113 corresponding to the pixel region 111. A drive element 117 is provided on pixel region 111, and this drive element 117 controls the light emitting operation of the organic EL element 112 on the bases of the image data stored in the capacitor 116 of the pixel region 111. Also formed in the display region 110 are a power supply line 118 which supply operation current to the organic EL element 112 provided in the plurality of pixel regions 111, and a reference potential line (cathode current line) 119 which gives reference potential to the organic EL element 112 or receives the operation current that had passed the organic EL element 112.

Also, at least one of the a scanning signal driver circuit which outputs scanning signal (control signal) to the scanning lines 113; a data signal driver circuit which outputs image data (data signal) to the data lines 114; and a light emission power source circuit which outputs operation current for the organic EL element 112 to the power supply line 118 may be formed in the main surface of the substrate 103.

FIG. 9 is a cross sectional view of the part where the drive element (thin film transistor) 117 and the organic EL element 112 are provided in one of the pixel region 111 shown in FIG. 8. On the main surface of the substrate 120 comprising an insulator material such as quarts or alkali-free glass, there are formed a semiconductor layer 121 which serves channel (active region) for the drive element 117; a first insulator film (gate insulator film) 122 covering the semiconductor layer 121; a control electrode (gate electrode) 123 which opposes the semiconductor layer 121 and which is separated from the semiconductor layer 121 by a first insulator layer 122; a second insulator film (interlayer insulator film) 124 covering the first insulator film 122 and the control electrode 123; and an output electrode (drain electrode) 125 which is disposed on the second insulator film 124, and which is also electrically connected to an end of the semiconductor layer (channel) 121 by a through hole extending through the first insulator film 122 and the second insulator film 124; in this order. The wiring which supplies the operation current to the other end of the semiconductor layer 121 is not shown due to the position of the cross section. The drive element 117 is constituted by the semiconductor layer 121, the first insulator film 122, the control electrode 123, and the output electrode 125.

On the main surface of the substrate 120, a leveling layer 126 is further formed from an insulator material to cover the second insulator film 124 and the output electrode 125, and a first electrode 127 of the organic EL element 112 is then formed from an electroconductive (conductive) material. The first electrode 127 contacts the output electrode 125 of the drive element 117 by the through hole formed through the leveling layer 126, and receives the operation current. An insulating partition wall 128 is formed on the leveling layer 126 to surround the first electrode 127, and this insulating partition wall 128 is also referred to as a bank and electrically isolates the organic EL elements 112 respectively formed on each of the adjacent pixel regions 111 from one another. When this organic electroluminescent display device is produced by the thin-film forming apparatus shown in FIG. 2(a) having the vapor deposition crucible 1 of the present invention mounted therein, the substrate 103 introduced in the vacuum chamber 2 and on which the organic material 36 is deposited is the substrate 120 having a main surface having the structure from the semiconductor layer 121 to the insulating partition wall 128 formed thereon. In other words, the substrate 103 is the structure shown in FIG. 9 from which an organic material layer 136 and a second electrode 129 of the organic EL element(s) 112 have been excluded.

The vapor deposition crucible 1 of the present invention forms the organic material layer 136 of the organic EL element 112 by vapor deposition of the organic material 36 on the upper surface of the first electrode 127 of the organic EL element 112 exposed from the insulating partition wall 128. On the main surface of the substrate 103 which is the workpiece material, a mask having the pattern corresponding to the first electrode 127 exposed from the opening of the insulating partition wall 128 is disposed to limit the vapor deposition of the organic material 36 on the upper surface of the insulating partition wall 128. This prevents the situation that the organic material layer 136 short-circuits the adjacent organic EL elements 112 by extending over the insulating partition wall 128 and contacting the adjacent first electrodes 127. The organic material layer 136 includes not only the light emitting layer but also the electron transfer layer, the hole transfer layer, and the like which promote injection of electron and positive hole to the light emitting layer. Accordingly, it is required that the organic materials having different molecular structure or composition are sequentially evaporated or sublimated for supply onto the main surface of the substrate 103 (upper surface of the first electrode 127).

For example, when the first electrode 127 is formed as an anode comprising ITO (indium tin oxide), IZO (indium zinc oxide), SnO₂ (tin oxide), In₂O₃ (indium oxide), Au, Ni, or the like, a hole transfer layer comprising TPD (N,N′-diphenyl-N,N′-di(3-methyphenyl)-4,4′-diaminobiphenyl) may be formed by vapor deposition on the first electrode. On this hole transfer layer, a light transmitting layer may be formed by sublimation and vapor deposition of a host material which is an aluminum—quinoline complex such as tris(8-quinolinol)aluminum (Alq₃) having added thereto a guest material (having a sublimation temperature lower than the host material) which is a dye such as 4-dicyanomethylene-6-(p-dimethylaminostylyl)-2-methyl-4H-pyran (DCM). An electron transfer layer is then formed on the light emitting layer by the sublimation and evaporation of solely the host material. Accordingly, the organic material layer 136 is formed as a laminate structure of a plurality of organic material layers comprising sequentially formed hole transfer layer, the light emitting layer, and the electron transfer layer. Such laminate structure may also comprise further organic material layers. On the upper surface of the organic material layer 136, a second electrode 129 may be formed as a cathode comprising Al, Li, Mg, Au, Ag, or an alloy thereof.

When a plurality of organic material layers are sequentially deposited on the main surface of the substrate 103 (upper surface of the first electrode 127) by vapor deposition in the thin-film forming apparatus shown in FIG. 2(a), the procedure used in quickly terminating the discharge of the vaporized organic material 360 from the vapor deposition crucible 1 (discharge aperture 81) after the completion of the vapor deposition step is also important. This procedure prevents, for example, contamination of the light emitting layer with the organic molecules used to constitute the hole transfer layer when the vapor deposition of the light emitting layer on the main surface of the substrate 103 is conducted subsequent to the vapor deposition of the hole transfer layer. During the vapor deposition of the light emitting layer on the main surface of the substrate 103, flying of the organic molecule that will form the hole transfer layer to the main surface of the substrate 103 is avoided by a shutter 11 or an auxiliary shutter 50a, 50b provided in the vacuum chamber 2. However, as long as the vapor deposition crucible 1 is not cooled, the vacuum chamber 2 is contaminated by the condensation of the organic molecule on the shutter 11 or the auxiliary shutter 50a, 50b. In contrast, in the vapor deposition crucible 1 according to the present invention, the organic material 360 evaporated or sublimed in the evaporation chamber 9 is introduced in the vacuum chamber 2 through the pressure-controlling chamber 10. The vaporized organic material 360 is introduced in the vacuum chamber 2 without condensing in the pressure-controlling chamber 10, and therefore, the desired organic material layer 136 is formed on the main surface of the substrate 103 even if amount of the organic material 36 evaporated or sublimed in the evaporation chamber 9 is suppressed. In addition, since the amount of the organic material 36 evaporated or sublimed is suppressed, upon completion of the vapor deposition step by the organic material, evaporation or sublimation of the organic material 36 in the evaporation chamber 9 can be terminated before starting or the subsequent vapor deposition step using different organic material. Of course, in the vapor deposition crucible 1 according to the present invention, amount of the evaporation or sublimation of the organic material 36 in the evaporation chamber 9 does not have to be increased at an accelerated pace at the start of the vapor deposition step using the organic material as in the case of the conventional vapor deposition crucible. Accordingly, a homogeneous organic material layer is formed on the main surface of the substrate 103 without contamination and at a high throughput. Therefore, when the vapor deposition method of the organic material according to the present invention is applied to the production of the organic electroluminescent display device, a product with high image quality can be produced at a high yield.

### EXAMPLE 2

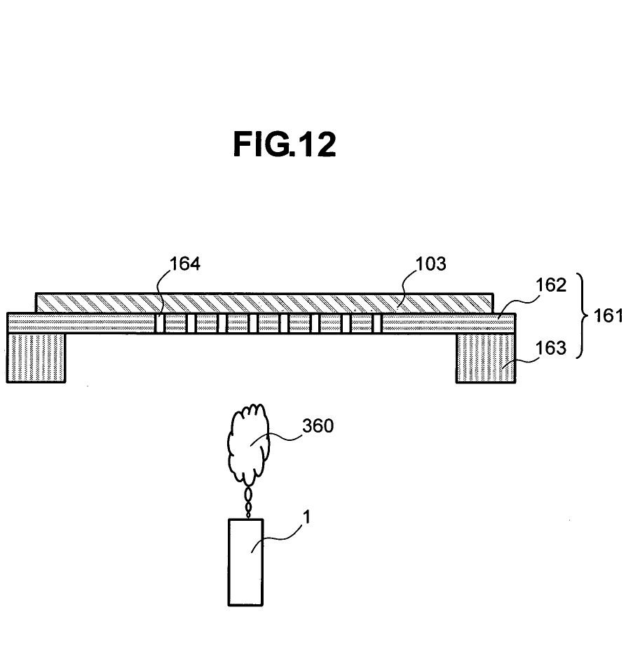

In this Example, a crucible structure adapted for use in the production of a display device (for example, organic EL panel) by mask vapor deposition is described. The inventors of the present invention investigated application of the present invention to the mask vapor deposition in which the vapor deposition layer is formed in a particular patterned region of the substrate 103. FIG. 12 shows the basic constitution (concept) of the mask vapor deposition. The formation of the vapor deposition layer on the main surface of the substrate 103 by the mask vapor deposition is carried out by bringing a vapor deposition mask 161 having a pattern of holes 164 corresponding to the pixels arranged in the main surface in close contact with the main surface of the substrate 103. The main surface of the substrate 103 before the mask vapor deposition is formed with the plurality of pixels, for example, defined by the insulating partition walls (banks) 128 described in relation to Example 1, and in each pixel, the first electrode 127 is exposed from the opening defined by the insulating partition wall 128. In an embodiment of such vapor deposition mask 161 which is brought in close contact with the substrate 103, a hole 164 is formed for each opening in the insulating partition wall 128.

As described above by referring to Patent Document 2, the vapor deposition mask 161 is generally prepared by adhering a metal sheet 162 having a main surface formed with the holes 164 to a metal frame 163. When mask vapor deposition to the substrate 103 is conducted with one of the main surfaces of the vapor deposition mask 161 in close contact with the substrate 103 and the other main surface facing the crucible 1 (the discharge aperture 81 of the crucible 1), temperature of the substrate 103 and the vapor deposition mask 161 increases by the heat of the crucible 1 or the heater 22 provided with the crucible 1. There is difference in thermal expansion between the substrate 103 comprising a glass and the vapor deposition mask 161 comprising a metal or an alloy, and the substrate 103 is changed every time the treatment is completed. Therefore, the heat radiated from the crucible 1 and the heater 22 causes displacement in the position of the substrate 103 (e.g., pattern of the pixel region 111) in relation to the vapor deposition mask 161 (pattern of the holes 164) according to the difference in the thermal expansion, and also, increase in the difference in the thermal expansion between the vapor deposition mask 161 which keeps receiving the radiant heat and the substrate 103 which is sequentially replaced with the increase in the number of mask vapor deposition of the substrates 103. In other words, displacement of the substrate 103 in relation to the vapor deposition mask 161 is not proportional to the number of mask vapor deposition, and displacement of the vapor deposition layer formed on the main surface of the substrate 103 from the target position is not decreased even if the vapor deposition mask 161 having the pattern of the holes 164 designed by taking such “displacement” into account were used. In order to reduce such displacement of the vapor deposited layer, the structure which minimizes the heat transfer from the crucible 1 to the vapor deposition mask 161 and the substrate 103 is necessary.

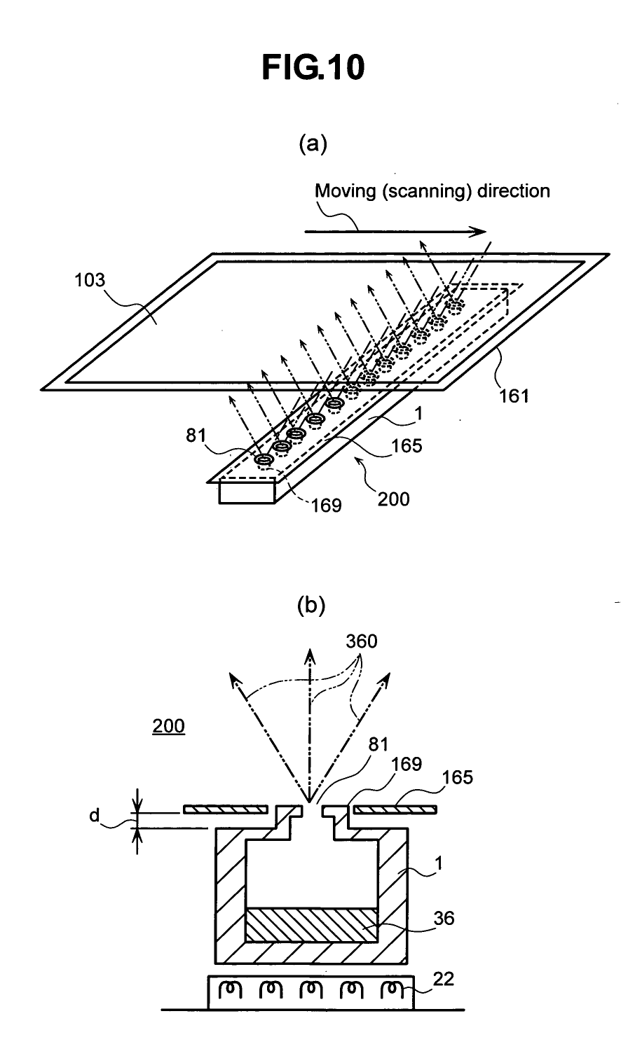

FIG. 10(B) shows conventional crucible for mask evaporation taught in Patent Document 2. A protrusion 169 is provided on the upper side of the crucible 1, and a discharge aperture 81 is formed at the upper end of the protrusion 169. The radiation blocking body 165 is placed at a position lower than the upper end of the protrusion 169 with its upper surface at a position substantially the same as the discharge aperture 81. Patent Document 2 discloses the technique of solving the prior art problem of providing a radiation blocking body on the side of the substrate (vacuum deposition mask) of the discharge aperture of the crucible by providing the radiation blocking body near the discharge aperture. Patent Document 2 also teaches use of a metal plate having a specular finished main surface on the side of the crucible 1 for the radiation blocking body, and contacting of the cooling member to the metal plate. As described above, influence of heat radiation from the crucible 1 on the substrate 103 and the vapor deposition mask 161 could be reduced by the radiation blocking body 165 which was placed at a distance more remote from the substrate 103 compared to the prior art as described above. However, in the crucible 1 disclosed in Patent Document 2, distance d between the upper surface of the crucible 1 and the radiation blocking body 165 is reduced, and the temperature of the upper surface and the discharge aperture 81 protruding from this upper surface which is remote from the heater 22 is reduced. The inventors of the present invention focused on the situation that the temperature decrease of the upper surface and the discharge aperture 81 of the crucible 1 is larger than that of the interior of the crucible where the material evaporates or sublimes, which invited the unfavorable precipitation of the material at the discharge aperture 81 to an unexpected degree that was likely to invite clogging of the discharge aperture.

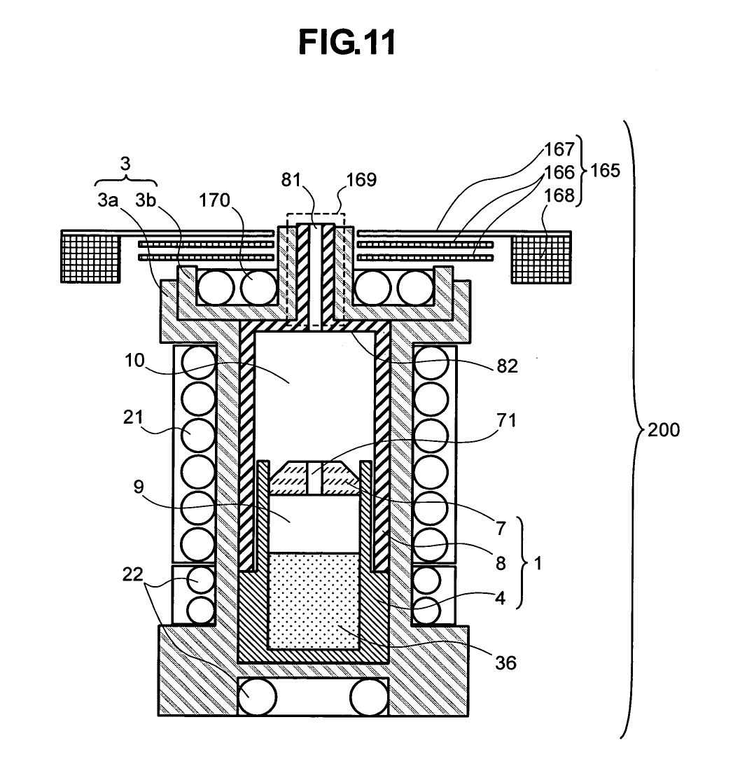

In order to solve such unfavorable situation, the inventors of the present invention provides a crucible structure of FIG. 11 which is adapted for use in the mask vapor deposition based on the crucible 1 discussed in Example 1. In order to suppress transfer of the radiant heat from the crucible 1 and the heater case 3 to the vapor deposition mask 161 and the substrate 103, a radiation blocking body having thermal insulating function (hereinafter referred to as insulation mechanism) 165 is provided above the crucible 1. Compared with the crucible 1 described in Example 1, the crucible 1 of this Example has the following characteristic features, namely, (1) the discharge plate 82 (constituting the upper surface of the crucible 1) is provided with the protrusion 169 extending from the its main surface to the exterior of the pressure-controlling chamber 10, (2) the discharge aperture 81 is formed on the end of the protrusion 169 remote from the discharge plate 82, and preferably, (3) the heater 170 is provided to oppose the exterior surface of the protrusion 169.

When the crucible 1 of the present invention including the one described in the Example 1 is mounted in a thin-film forming apparatus placed in a gravity field, the crucible main body 4 is placed at the lower side of the crucible 1 and the discharge plate 82 is placed on the upper side of the crucible 1, respectively. When the vertical direction of the crucible 1 is defined in this way, the protrusion 169 extends upward from the discharge plate 82 and the discharge aperture 81 is formed on the upper end of the protrusion 169, and the heater 170 opposes the side surface of the protrusion 169. When the lower surface of the discharge plate 82 (opposing the orifice plate 7) shown in FIG. 11 is defined the first main surface, and the upper surface (the main surface opposite to the first main surface) is defined the second main surface, respectively, the protrusion 169 extends upward from the second main surface of the discharge plate 82. In other words, the protrusion 169 extends outwardly from the pressure-controlling chamber 10 formed as a space between the orifice plate 7 and the opposing first main surface of the discharge plate 82, and the second opening 81 is formed at its tip (distal end). In the interior of the protrusion 169, a passage for the evaporated material is formed from the lower surface side of the discharge plate 82 (interior of the pressure-controlling chamber 10) to the discharge aperture 81. In other words, the protrusion 169 can be described as a nozzle discharging the evaporated material. The protrusion 169 may be formed as an integral part with the discharge plate 82 of the cap 8 including the discharge plate. It is to be noted that the container portion in which the material 36 evaporated from the crucible 1 is referred to as the bottom part of the crucible main body 4. In FIG. 11, the heater 170 also opposes the upper surface (exterior surface) of the discharge plate 82. The heater case 3 comprises the first heater case 3a accommodating “the lower heater 22 (for heating the evaporation chamber 9) which is arranged to oppose the side surface and the lower surface of the crucible 1” and “the upper heater 21 (for heating the pressure-controlling chamber 10) which is arranged to oppose the side surface of the crucible 1”, and the second heater case 3b accommodating “the heater 170 (for heating the protrusion 169) which is arranged to oppose the upper surface of the crucible 1”. The first heater case 3a may also be formed as a vessel accommodating the crucible main body 4 and the cap 8 in its interior. As in the case of the conventional structure shown in FIG. 10(A), the crucible 1 (the crucible main body 4 and the cap 8) of FIG. 11 may be dilated in the transverse direction, and two or more protrusions 169 each having the discharge aperture 81 formed therewith may be formed in one dimensional or two dimensional manner on the dilated upper surface (discharge plate 82) of the crucible.

The insulation mechanism (the radiation blocking body having the thermal insulator function) 165 according to the present invention is provided with the at least one reflection plate 166, the cooling plate 167, and a cooling apparatus 168 connected to this cooling plate 167 disposed in this order along the direction of the extension of the protrusion 169 on the upper surface (discharge plate 82) of the crucible 1 of this Example. A metal plate or an alloy plate (hereinafter generally referred to as the metal plate) having at least one of its main surface specular finished is used for the reflection plate 166, and this metal plate is placed so that the main surface opposes to the upper surface of the crucible 1. The reflection plate 166 may also comprise a metal plate having both of its main surfaces specular finished. The upper surface of the crucible 1, the reflection plate 166, and the cooling plate 167 are spaced at a predetermined distance, and these are thermally isolated from each other. As shown in FIG. 11, the insulation mechanism 165 may include two or more reflection plates 166 between the upper surface of the crucible 1 and the cooling plate 167 which are spaced at a predetermined distance. The two or more reflection plates 166 are provided so that their “specular finished surface” formed as at least one of their main surfaces faces the upper surface of the crucible 1. The cooling plate 167 is provided so that its main surface opposes the main surface of the adjacent reflection plate 166, and this cooling plate 167 is formed from a material having a high thermal conductivity. For example, the cooling plate 167 may preferably have a thermal conductivity lower than that of the reflection plate 166. The cooling plate 167 is connected to an insulator apparatus 168 having a water cooling mechanism or a Peltier device. The insulation mechanism 165 of the present invention is constituted as described above. The reflection plate 166 may be prepared by polishing a material (a plate member) comprising a material like stainless steel or aluminum, or by plating chromium or the like on a metal alloy to thereby form a specular surface. The cooling plate 167 may be formed from a material having a high thermal conductivity such as copper and aluminum.

When this insulation mechanism 165 is located beyond, namely, to the side of the substrate 103 of the discharge aperture 81 of the crucible 1, vapor of the material 36 from the discharge aperture 81 will deposit and precipitate on the reflection plate 166 and the cooling plate 167, and when such layer formation of the material 36 on the substrate 103 is repeated for a long time, loss in the thermal insulation performance of the insulation mechanism 165 and clogging of the discharge aperture 81 are invited. As shown in FIG. 11, in the crucible 1 of this Example, the protrusion 169 is formed on the upper side of the cap 8 and the discharge aperture 81 is formed on the upper end of the protrusion 169 in order to solve such problem. Since the tip of the protrusion 169 is located beyond, namely, to the side of the substrate 103 of the insulation mechanism 165, the material 36 exiting from the discharge aperture 81 is prevented from depositing on the insulation mechanism 165. In addition, since a heater 170 for heating the side surface of the protrusion 169 is provided, decrease in the temperature of the discharge aperture 81 is suppressed even though the cooling plate 167 is placed in the vicinity of the protrusion 169. The problem of the decrease in the temperature of the discharge aperture 81 can be substantially solved by forming the second heater case 3b accommodating the heater 170 from a metal or an alloy (for example, stainless steel) having a high thermal capacity or a metal or alloy (for example, aluminum of an alloy thereof) having a high thermal conductivity, and by inserting a part of the second heater case 3b between the protrusion 169 and the cooling plate 167. In addition, since the reflection plate 166 inserted between the heater 170 and the cooling plate 167 thermally insulate the heater 170 and the cooling plate 167, both the efficiency of heating the protrusion 169 by the heater 170 and the efficiency of cooling the substrate 103 and the mask 161 by the cooling plate 167 are improved. Since decrease in the temperature of the discharge aperture 81 in relation to the interior of the crucible 1 (in particular, the pressure-controlling chamber 10) is suppressed, clogging of the discharge aperture 81 by the precipitation of the material 36 is prevented. It should also be noted, provision of the two-chamber structure (comprising the evaporation chamber 9 and the pressure-controlling chamber 10) in the crucible 1 has realized stable transpiration of the material from the crucible 1. The heater 170 is also referred to as the “discharge nozzle heater” since it controls the temperature of the protrusion 169 which serves the “discharge nozzle of the evaporated material” for the crucible 1.

The insulation mechanism 165 comprises at least one plate member which serves the reflection plate 166 and another plate member serving the cooling plate 167 which are arranged in the direction of the protrusion 169 extending outwardly from the discharge plate 82. The reflection plate 166, the cooling plate 167, and the cooling apparatus 168 depicted in FIG. 11 as if they were floating may be secured, for example, to the interior of the vacuum chamber (chamber) 2 of the thin-film forming apparatus, or to the constituent member of the crucible 1 (for example, the heater case 3b). However, the reflection plate 166 is thermally isolated from the cooling plate 167, and each of the reflection plate 166 and the cooling plate 167 is thermally isolated from the crucible 1 (in particular, the protrusion 169 and the discharge plate 82). The cooling plate 167 and the cooling apparatus 168 may be connected by a member like a cold finger having a high thermal conductivity. The reflection plate 166 is arranged so that one of its main surfaces (the one having the specular surface) opposes at least the upper heater 21 (and the discharge nozzle heater 170 when it is provided), and preferably, so that the entire area of the other main surface of the reflection plate 166 opposes the main surface of the cooling plate 167. When the crucible 1 is seen from the substrate 103 (the vapor deposition mask 161) in vertical direction, the upper heater 21 (and the discharge nozzle heater 170) is preferably covered by the reflection plate 166, and preferably, the reflection plate 166 is also covered with the cooling plate 167. Preferably, the lower heater 22 which is more remote from the substrate 103 compared to the upper heater 21 and which is provided along the side surface of the crucible 1 is also covered with the reflection plate 166. While the main surface of the plate members used for the reflection plate 166 and the cooling plate 167 are not particularly limited for their shape (the shape of the plane), the main surface of the reflection plate 166 is preferably determined according to the shape of the plane of the upper heater 21 (and the discharge nozzle heater 170). As in the case of conventional radiation blocking body 165 shown in FIG. 10(A), a plate member having openings through which the protrusions 169 can be inserted may be used for the reflection plate 166 and the cooling plate 167. When the cap 8 shown in FIG. 11 is extended in the direction perpendicular to the vertical direction of the crucible 1 and a plurality of protrusions 169 are arranged in one dimensional or two dimensional manner on its upper surface (the discharge plate 82), a plate member having a main surface in which openings corresponding to the protrusions 169 are defined is preferably used for the reflection plate 166 and the cooling plate 167.

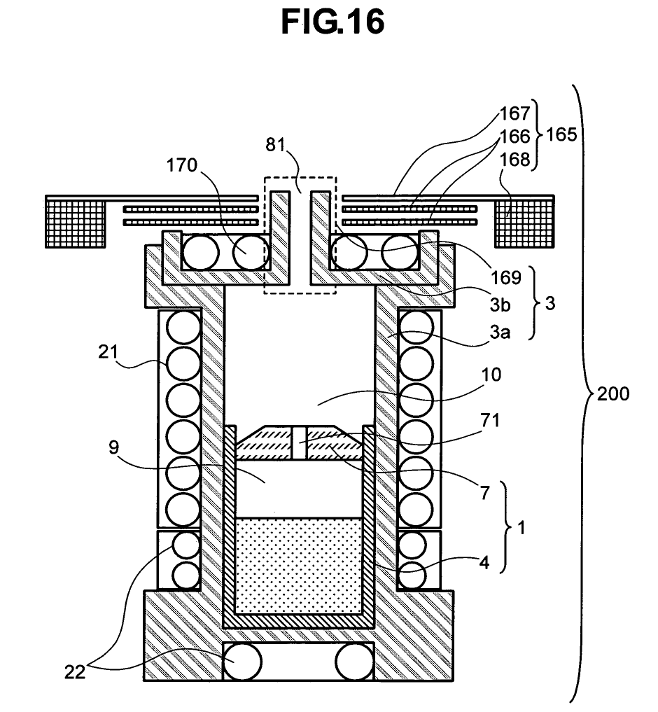

In the crucible 1 shown in FIG. 11, the discharge plate 82, the outer periphery of the side wall 83, and the protrusion 169 each constituting the cap 8 are heated by the heaters 21, 22, 170 via the heater case 3. However, at least one of these members exemplified as the discharge plate 82, the side wall 83, and the protrusion 169 may be integrated with the heater case 3. Therefore, the structure of the crucible 1 shown in FIG. 11 can be simplified as shown in FIG. 16. In the crucible 1 shown in FIG. 16, the side wall 83 of the cap 8 is integrated with the first heater case 3a, while the discharge plate 82 and the protrusion 169 formed thereat are integrated with the second heater case 3b. Namely in the crucible 1 shown in FIG. 16, the function of the cap 8 (each of functions of the discharge plate 82, the side wall 83, and the protrusion 169) is provided for the heater case 3 (the first and second heater cases 3a, 3b). Regarding the first heater case 3a as the side wall 83 of the cap 8 in FIG. 16, the side wall 83 of the cap 8 is provided with the aforementioned upper and lower heaters 21, 22 each of which is directly in contact therewith. Regarding the second heater case 3b as the integration of the discharge plate 82 and the protrusion 169 in FIG. 16 also, each of the discharge plate 82 and the protrusion 169 is provided with the discharge nozzle heater 170 to be directly in contact therewith. The crucible 1 shown in FIG. 16 reduces a number of parts required for an assembly thereof in comparison with that shown in FIG. 11 so that a number of interfaces on the heat transfer passage from the heaters 21, 22, 170 to the members 82, 83, 169 to be heated thereby can be reduced. Since heat generated by the heaters 21, 170 is transferred to the pressure-controlling chamber 10 only through the heater case 3 in FIG. 16, its heating efficiency can be improved.

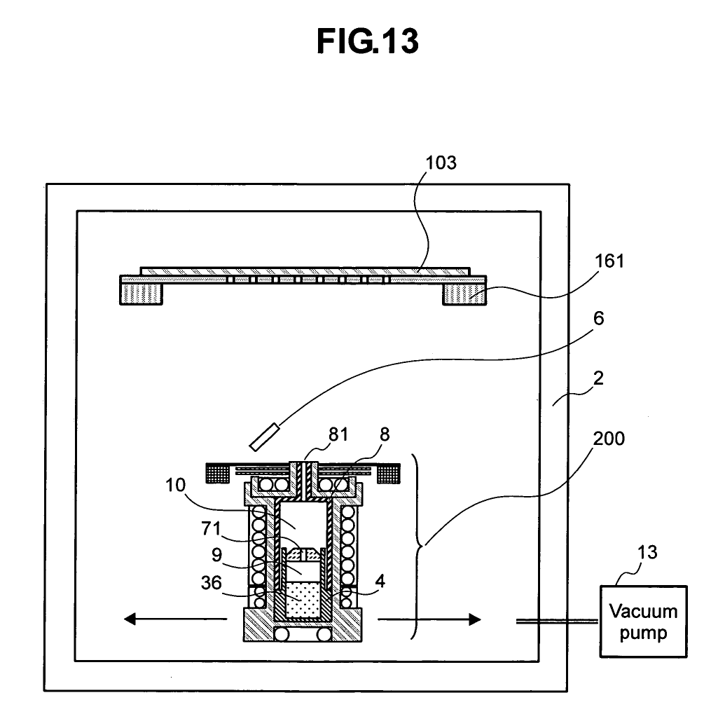

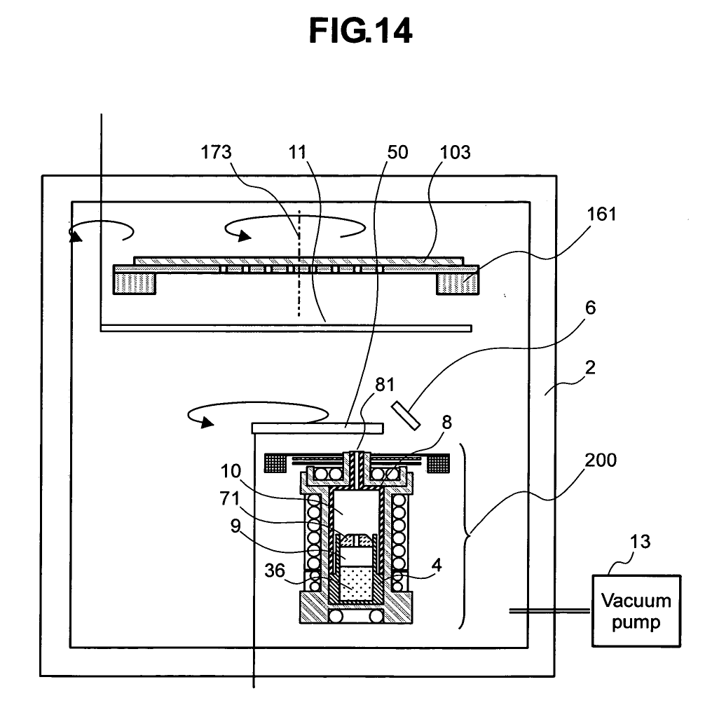

The vapor evaporation apparatus (thin-film forming apparatus) provided with the vapor deposition source 200 including the crucible 1, the heater case 3, and the insulation mechanism 165 shown in FIG. 11 is schematically shown in FIGS. 13 and 14, respectively. The substrate 103 is placed in the upper part of the vacuum chamber 2 with its main surface (the surface on which the material 36 is formed) facing downward, and with the vapor deposition mask 161 in close contact with the main surface. The vapor deposition source 200 according to the present invention is placed in the lower part of the vacuum chamber 2. The discharge aperture 81 of the crucible 1 and the vapor deposition mask 161 (the substrate 103) are separated in the vertical direction of the crucible 1. Since FIG. 11 is schematically drawn, the actual distance between the discharge aperture 81 and the vapor deposition mask 161 may be shorter than the size in the vertical direction of the crucible 1 (height of the crucible 1 from the heater case 3a to the upper end of the discharge aperture 81). In the vapor deposition apparatus shown in FIG. 13, position of the vapor deposition source 200 within this main surface moves back and forth (in horizontal direction of the drawing) during the period in which the material 36 is deposited on the main surface of the substrate 103 (deposition period). In the vapor deposition apparatus of FIG. 13, the vapor deposition source 200 is preferably moved to the end either in the left or right direction in the drawing during the waiting period (for example, the period when the substrate 103 is replaced with a new substrate 103 between the deposition periods) to thereby separate the vapor deposition source 200 from the substrate 103 to prevent deposition of the excessive evaporated material on the substrate 103. On the other hand, when the position of the vapor deposition source 200 in relation to the main surface of the substrate 103 is fixed during the deposition period, the substrate 103 is preferably rotated with the vapor deposition mask 161 kept in close contact with the substrate 103 as shown in FIG. 14. In this process, when the position of the vapor deposition source 200 is deviated from the rotary shaft 173 of the substrate 103, the layer of the material 36 formed on the main surface will have an improved homogeneity. In addition, as shown in FIG. 14, a main shutter 11 and an auxiliary shutter 50 are provided and the position of the main shutter 11 and the auxiliary shutter 50 can be adjusted from the exterior of the vacuum chamber 2. In the waiting period as described above, the auxiliary shutter 50 is located above the discharge aperture 81 of the crucible 1 to thereby prevent deposition of the material on the substrate 103. On the other hand, during the deposition of the material 36 on the substrate 103, the main shutter 11 is displaced from the main surface of the substrate 103, and the auxiliary shutter 50 is also displaced from the discharge aperture 81 of the crucible 1 to thereby supply the material ejected from the crucible 1 (for example, the vapor of the material 36) to the substrate 103. The main shutter 11 can also be provided in the vapor deposition apparatus of FIG. 13 to prevent the deposition of the excessive evaporated material on the substrate 103.

In each of the vapor evaporation apparatus shown in FIGS. 13 and 14, a sensor 6 is provided to measure the amount of the evaporated material supplied from the crucible 1 to the substrate 103 per unit time. This provision of the sensor 6 enables monitoring supply of the evaporated material 360 by the crucible 1, and temperature setting of the heaters 21, 22, and 170, moving speed of the vapor deposition source 200, the rotation speed of the substrate 103, and the processing time of each substrate 103 can be adequately determined by referring to the sensor 6. While each of the vapor evaporation apparatus shown in FIGS. 13 and 14 is equipped with the crucible 1 shown in FIG. 11, the crucible 1 may be replaced by that shown in FIG. 16 as explained above.

### EXAMPLE 3

This Example shows another embodiment for the orifice plate 7 and its opening portion 71 of the crucible 1 described in Examples 1 and 2. The orifice plate 7 shown in FIGS. 1, 3, 11, 13, and 14 is formed with an opening portion 71 extending in vertical direction of the crucible 1.

In this Example, the opening portion 71 of the orifice plate 7 is not formed in the orifice plate 7 but the opening portion 71 is formed as a gap between the orifice plate 7 and the inner wall of the crucible main body 4 (the part where the orifice plate 7 is supported). The orifice plate 7 shown in FIG. 15 is a block member having no opening formed therethrough. While this orifice plate 7 is depicted as if it was floating in the upper portion of the crucible main body 4, it is actually supported by at least 1 support member, and preferably, by several support members (not shown) to the crucible main body 4. In other words, the opening portion 71 is formed as a region defined by the outer wall of the orifice plate 7, the supporting member(s), and the crucible main body 4 (inner wall). In the orifice plate 7 as described above, the opening portion 71 (passage of the evaporated material) is heated by the lower heater 22 through the heater case 3, the crucible main body 4, and the orifice plate 7, and therefore, the heat generated by the lower heater 22 is transferred to the opening portion 71 across these three interfaces. In this Example, the opening portion 71 is heated by the lower heater 22 through the heater case 3 and the crucible main body 4, and the number of the interfaces present in the transfer pathway of the heat generated in the lower heater 22 is reduced to two. Accordingly, temperature of the opening portion 71 (the orifice hole) will increase in relation to the temperature set for the lower heater 22 (when heater is turned on), and the evaporated material will be less likely to deposit at the opening portion 71 and the area near this opening portion 71. This stabilizes the amount of the material 36 evaporated or vaporized in the evaporation chamber 9 (the interior of the crucible main body 4) to the pressure-controlling chamber 10 (the space defined by the crucible main body 4, the outer wall of the orifice plate 7, and the inner wall of the cap 8).

This present invention can be used as a vapor deposition crucible for use in a vapor deposition system for vapor depositing an organic material. The method for vapor depositing an organic material of the present invention can be used in producing a display device as typically represented by an organic electroluminescent display device.

While we have shown and described several embodiments in accordance with the present invention, it is understood that the same is not limited thereto but is susceptible of numerous changes and modifications as known to those skilled in the art, and we therefore do not wish to be limited to the details shown and described herein but intend to cover all such changes and modifications as are encompassed by the scope of the appended claims.

What is claimed is:

1. A vapor deposition crucible used for a vapor deposition source in a thin-film forming apparatus comprising:
a container portion where material to be evaporated from the vapor deposition crucible is accommodated;
an orifice plate having a first opening, the orifice plate being separated from the container portion by a first space; and
discharge plate provided on outer side of the first space and separated from the orifice plate by a second space, and having a second opening which discharges the material to the exterior of the vapor deposition crucible; wherein
an evaporation chamber for the evaporation of the material is formed between the container portion and the orifice plate in the first space; and
the second space serves a pressure-controlling chamber in which the pressure is controlled in relation to the evaporation chamber.

2. A vapor deposition crucible used for a vapor deposition source in a thin-film forming apparatus comprising:
a vessel having a portion where material to be evaporated from the vapor deposition crucible is accommodated;
an orifice plate having a first opening and being provided in the vessel; and
a discharge plate provided on outer side of the vessel to oppose the orifice plate, and having a second opening which discharges the material evaporated in the vapor deposition crucible to the exterior of the vapor deposition crucible; wherein
an evaporation chamber is formed in the vessel between the portion where the material is filled and the orifice plate; and
a space is defined between the orifice plate and the discharge plate, and this space serves a pressure-controlling chamber in which the pressure is controlled in relation to the evaporation chamber.

3. The vapor deposition crucible according to claim 2, wherein
the second opening is formed at distal end of a protrusion extending from the discharge plate toward the exterior of the pressure-controlling chamber;
at least one reflection plate provided at a distance from the discharge plate and a cooling plate spaced from the reflection plate are arranged from the discharge plate in this order in the direction of the extension of the protrusion;
the reflection plate has a specular finished main surface on the side of the discharge plate; and
the cooling plate is connected to a cooling apparatus, and one of main surfaces of the cooling plate is wider than the main surface of the reflection plate, and distance between another of the main surfaces of the cooling plate and the discharge plate is equal to or shorter than distance between the distal end of the protrusion and the discharge plate.

4. The vapor deposition crucible according to claim 3, wherein
a heater is provided on sides of the protrusion, the pressure-controlling chamber and the evaporation chamber,
the specular finished main surface of the reflection plate adjacent to the discharge plate opposes the heater with an intervening gap, and
the one of the main surfaces of the cooling plate is shielded from the heater by the reflection plate.

5. The vapor deposition crucible according to claim 3, wherein
a plurality of reflection plates are juxtaposed at a distance between each other in the direction of the extension of the protrusion, between the discharge plate and the one of the main surfaces of the cooling plate.

6. The vapor deposition crucible according to claim 3, wherein
the orifice plate is inserted in the interior of the vessel at its one end,
the one end of the vessel is provided with a support for supporting the orifice plate,
the discharge plate is formed with a side wall extending from the surface formed with the second opening to the exterior of the end of the vessel, and
the pressure controlling chamber is formed between exterior periphery of the end of the vessel, and the surface of the discharge plate and the side wall thereof covering the exterior periphery.

7. The vapor deposition crucible according to claim 6 further comprising a heater provided on sides of the protrusion, the pressure-controlling chamber, and the evaporation chamber, wherein
the heater is provided for the discharge plate at each of the surface thereof, the side wall thereof extending from the surface along an outer periphery of the pressure-controlling chamber, and the protrusion thereof having the second opening and extending from the surface thereof so that the heater is directly in contact with the each of the surface, the side wall, and the protrusion.

8. The vapor deposition crucible according to claim 6 further comprising a heater provided on sides of the protrusion, the pressure-controlling chamber, and the evaporation chamber and a heater case accommodating the heater, wherein
the heater case is provided with each of functions of the surface, the side wall, and the protrusion of the discharge plate.

9. The vapor deposition crucible according to claim 2, wherein
the first opening is formed as a gap defined between the orifice plate and the side surface of the vessel opposite thereto.

10. The vapor deposition crucible according to claim 1, wherein
vapor pressure of the material in the pressure-controlling chamber is kept to the level not exceeding that in the evaporation chamber where the material is evaporated.

11. The vapor deposition crucible according to claim 1 further comprising
a first heater for heating the evaporation chamber and a second heater for heating the pressure-controlling chamber,
the first heater and the second heater being controlled independently from each other.

12. The vapor deposition crucible according to claim 1, wherein
the evaporation chamber is maintained at a temperature lower than that of the pressure-controlling chamber.

13. A thin-film forming apparatus having the vapor deposition crucible of claim 1 as a vapor deposition source, comprising
a chamber into which a substrate on which the material evaporated in the evaporation chamber is to be deposited is introduced, and
at least one vapor deposition crucible which is connected to the chamber by the second opening, wherein
the chamber is maintained at a pressure lower than any of the evaporation chamber and the pressure-controlling chamber.

14. A thin-film forming apparatus having the vapor deposition crucible of claim 3 as a vapor deposition source, comprising
a chamber into which a substrate on which the material evaporated in the evaporation chamber is to be deposited is introduced,
a vapor deposition mask which has a plane formed with a plurality of holes corresponding to the pixel pattern to be formed on a main surface of the substrate, and which is brought in close contact with the main surface of the substrate at the plane, and
at least one vapor deposition crucible which is connected to the chamber by the second opening, wherein
in the chamber, the vapor deposition mask is provided such that the main surface of the substrate having the plane of the vapor deposition mask closely contacted therewith opposes the second opening of the vapor deposition crucible, and
the chamber is maintained at a pressure lower than any of the evaporation chamber and the pressure-controlling chamber.

15. A method for producing a display device by vapor depositing an organic material on main surface of a substrate, comprising the steps of:
evaporating the organic material in a first space;
introducing the evaporated organic material from the first space to a second space in which vapor pressure of the organic material is maintained to the level not higher than the first space; and
introducing the evaporated organic material which has been introduced in the second space to a third space which is maintained at a pressure lower than the first space and the second space, and depositing the evaporated organic material onto the main surface of the substrate disposed in the third space.

16. The method for producing a display device according to claim 15, wherein
the second space is maintained at a temperature higher than that of the first space.

17. The method for producing a display device according to claim 16, wherein
the second space and the third space are connected by an opening formed in a member separating the second space and the third space, and
the evaporated organic material is introduced from the second space to the third space through the opening while the opening is maintained at a temperature not lower than the temperature of the second space.

18. The method for producing a display device according to claim 17, wherein
space of the third space surrounding the opening is cooled to a temperature lower than the temperature of the opening.

19. The method for producing a display device according to claim 16, wherein
the step of the vapor deposition of the evaporated organic material onto the main surface of the substrate is terminated by stopping the heating of the second space after stopping the heating of the first space.
